(19) United States
(12) Patent Application Publication
(10) Pub. No.: US 2026/0255690 A1
(43) Pub. Date: Aug. 27, 2026

(54) ELECTROSTATIC DISCHARGE DEVICE IN STACKED NANOSHEET TRANSISTORS

(71) Applicant: INTERNATIONAL BUSINESS MACHINES CORPORATION, ARMONK, NY (US)

(72) Inventors: Robert Gauthier, Williston, VT (US); Anindya Nath, Watervliet, NY (US); Masoud Zabihi, Schenectady, NY (US); Brent Alan Anderson, Jericho, VT (US); Tenko Yamashita, Schenectady, NY (US); Lijuan Zou, Albany, NY (US); Chen Zhang, Santa Clara, CA (US)

(21) Appl. No.: 19/064,554

(22) Filed: Feb. 26, 2025

(51) Int. Cl. H10D 89/60

(52) U.S. Cl. CPC H10D 89/814; H10D 89/713

(57) ABSTRACT

A semiconductor device includes a passive device including a top device including a top N-type doped region and a top P-type doped region separated by a top gate region, a first frontside contact and a second frontside contact over the top N-type doped region and the top P-type doped region, respectively. The semiconductor device further includes a bottom device including a bottom P-type doped region and bottom N-type doped region separated by a bottom gate region, and a first backside contact and a second backside contact below the bottom N-type doped region and the bottom P-type doped region, respectively, and a well region electrically connecting the top device to the bottom device.

### BACKGROUND

### Technical Field

The present disclosure generally relates to semiconductors, and more particularly, to electrostatic discharge device in stacked transistors with nanosheet channel structure, and methods of creation thereof.

### Description of Related Art

The relentless miniaturization of transistors and their increasing density on chips epitomize the semiconductor industry's innovation, largely adhering to Moore's Law. This trend has led to transistors shrinking to nanometer scales, allowing millions and even billions to fit on a single chip, significantly enhancing computational power and energy efficiency. The evolution towards system-on-chip architectures integrates various functionalities, including processing and sensing, on one chip.

### SUMMARY

According to an embodiment, a semiconductor device includes a top device having a top N-type doped region and a top P-type doped region separated by a top gate region, and a first frontside contact and a second frontside contact over the top N-type doped region and the top P-type doped region, respectively, and a bottom device including a bottom P-type doped region and bottom N-type doped region separated by a bottom gate region; and a first backside contact and a second backside contact below the bottom N-type doped region and the bottom P-type doped region, respectively, and a well region electrically connecting the top device to the bottom device.

In one embodiment, each of the top device and the bottom device includes a set of nanosheet channels extended horizontally across a gate.

In one embodiment, the top device and the bottom device form a vertical device and a lateral device in a same structure, wherein the vertical device and the lateral device are in parallel.

In one embodiment, the well region is at least one of: an in situ-doped intermediate semiconductor layer or an implant layer.

In one embodiment, the semiconductor device includes an input contact and an output contact, wherein at least one of the top device or the bottom device is a bipolar junction, and the input contact and the output contact are at a same metallization level.

In one embodiment, the semiconductor device includes an input contact and an output contact, and the semiconductor device forms a diode, and the input contact and the output contact are located on opposite sides of the semiconductor device or a same side of the semiconductor device.

In one embodiment, the set of nanosheet channels is adjacent to an active device layer and is electrically connected, and the top gate regions and the bottom gate regions are adjacent to the active device layer and are electrically isolated.

In one embodiment, the well region is an N-well region or a P-well region.

In one embodiment, the well region is electrically connected to the top P-type doped region, the top N-type doped region, the bottom P-type doped region and the bottom N-type doped region.

According to an embodiment, a method for fabrication of a semiconductor device includes forming a top device having a top N-type doped region and a top P-type doped region separated by a top gate region, and forming a first frontside contact and a second frontside contact over the top N-type doped region and the top P-type doped region, respectively, and forming a bottom device, forming a bottom P-type doped region and bottom N-type doped region separated by a bottom gate region and forming a first backside contact and a second backside contact below the bottom N-type doped region and the bottom P-type doped region, respectively, and forming a well region electrically connecting the top device to the bottom device.

In some embodiments, forming each of the top device and the bottom device further includes forming a set of nanosheet channels extended horizontally across a gate.

In some embodiments, the top device and the bottom device form a vertical device and a lateral device in a same structure, and the vertical device and the lateral device are in parallel.

In some embodiments, the well region is at least one of: an in situ-doped intermediate semiconductor layer or an implant layer.

In some embodiments, the method includes forming an input contact and an output contact, and at least one of the top device or the bottom device is a bipolar junction, and the input contact and the output contact are at a same metallization level.

In some embodiments, the method includes forming an input contact and an output contact, and the semiconductor device forms a diode, and the input contact and the output contact are located on opposite sides of the semiconductor device or a same side of the semiconductor device.

In some embodiments, the set of nanosheet channels is adjacent to an active device layer and is electrically connected, and the top gate regions and the bottom gate regions are adjacent to the active device layer and are electrically isolated.

In some embodiments, the method includes doping the well region with an N-type dopant or a P-type dopant.

In some embodiments, the method includes electrically connecting the well region to the top P-type doped region, the top N-type doped region, the bottom NP-type doped region and the bottom N-type doped region.

According to an embodiment, a semiconductor device includes a top device having a top N-type doped region and a top P-type doped region separated by a top gate region, a bottom device comprising a bottom P-type doped region and bottom N-type doped region separated by a bottom gate region, and a well region electrically connecting the top device to the bottom device.

In some embodiments, the semiconductor device includes a first frontside contact and a second frontside contact over the top N-type doped region and the top P-type doped region, respectively, and a first backside contact and a second backside contact below the bottom N-type doped region and the bottom P-type doped region, respectively, and wherein each of the top device and the bottom device further comprises a set of nanosheet channels extended horizontally across a gate.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIGS. 1A-1B illustrate schematically an ESD device operation during the normal circuit operation voltage range, ESD operating window during an ESD event, and the failure region.

FIG. 1C illustrates a conventional planar semiconductor device with shallow trench isolation.

FIGS. 1D-1E illustrate circuitry of the semiconductor device shown in FIG. 1C.

FIG. 1F illustrates an I-V curve of the semiconductor device shown in FIG. 1C.

FIGS. 2A-2B illustrate conventional electrostatic discharge devices with shallow trench isolation.

FIG. 3A illustrates a set of diodes, in accordance with some embodiments.

FIG. 3B illustrates stacked FET ESD diagonal bipolars, in accordance with some embodiments.

FIG. 3C illustrates stacked FET ESD vertical/lateral silicon-controlled rectifier, in accordance with some embodiments.

FIG. 3D illustrates a FET region of the semiconductor device.

FIGS. 4A-4C illustrate circuitry representing the semiconductor device of FIGS. 3A-3C, respectively.

FIG. 4D illustrates an I-V diagram of the semiconductor device of FIG. 3A.

FIG. 4E illustrates an I-V diagram of the semiconductor device of FIGS. 3B-3C.

FIG. 5 illustrates a semiconductor device after the growing the first half of the nanosheet stack, in accordance with some embodiments.

FIG. 6 illustrates a semiconductor device after the implantation of the passive device, in accordance with some embodiments.

FIG. 7 illustrates a semiconductor device after the removal of the organic planarization layer, in accordance with some embodiments.

FIG. 8 illustrates a semiconductor device after the removal of the substrate from the logic device, in accordance with some embodiments.

FIG. 9 illustrates a semiconductor device after the growing the high-Ge SiGe layer, in accordance with some embodiments.

FIG. 10 illustrates a semiconductor device after the removal of the high-Ge SiGe layer from the passive device, in accordance with some embodiments.

FIG. 11 illustrates a semiconductor device after the removal of the organic planarization layer, in accordance with some embodiments.

FIG. 12 illustrates a semiconductor device after the formation of the second half of the nanosheet stack, in accordance with some embodiments.

FIG. 13 illustrates a semiconductor device after the formation of the hard masks, in accordance with some embodiments.

FIG. 14 illustrates a semiconductor device after the formation of dummy gates, in accordance with some embodiments.

FIG. 15 illustrates a semiconductor device after the formation of spacers, the middle dielectric isolation and the bottom dielectric isolation, in accordance with some embodiments.

FIG. 16 illustrates a semiconductor device after the formation of inner spacer and the liner, in accordance with some embodiments.

FIG. 17 illustrates a semiconductor device after the formation of sacrificial placeholders in accordance with some embodiments.

FIG. 18 illustrates the semiconductor device after the formation oxide backfill, in accordance with some embodiments.

FIG. 19 illustrates the semiconductor device after the patterning of the frontside of the semiconductor device, in accordance with some embodiments.

FIG. 20 illustrates the semiconductor device after the removal of the OPL, in accordance with some embodiments.

FIG. 21 illustrates the semiconductor device after the formation of the liner, in accordance with some embodiments.

FIG. 22 illustrates the semiconductor device after the recession of the semiconductor device, in accordance with some embodiments.

FIG. 23 illustrates the semiconductor device after the formation of the bottom doped region, in accordance with some embodiments.

FIG. 24 illustrates the semiconductor device after the formation of the oxide layer, in accordance with some embodiments.

FIG. 25 illustrates the semiconductor device after the formation of the liner, in accordance with some embodiments.

FIG. 26 illustrates the semiconductor device after the formation of the OPL, in accordance with some embodiments.

FIG. 27 illustrates the semiconductor device after the removal of the OPL, in accordance with some embodiments.

FIG. 28 illustrates the semiconductor device after the recession of the oxide layer, in accordance with some embodiments.

FIG. 29 illustrates the semiconductor device after the removal of the liner, in accordance with some embodiments.

FIG. 30 illustrates the semiconductor device after the formation of the bottom doped region, in accordance with some embodiments.

FIG. 31 illustrates the semiconductor device after the formation of the oxide layer, in accordance with some embodiments.

FIG. 32 illustrates the semiconductor device after the recession of the oxide layer, in accordance with some embodiments.

FIG. 33 illustrates the semiconductor device after the doping of the bottom doped region, in accordance with some embodiments.

FIG. 34 illustrates the semiconductor device after the removal of the OPL, in accordance with some embodiments.

FIG. 35 illustrates the semiconductor device after the removal of the liner, in accordance with some embodiments.

FIG. 36 illustrates the semiconductor device after the formation of the top doped region, in accordance with some embodiments.

FIG. 37 illustrates the semiconductor device after the removal of the oxide, in accordance with some embodiments.

FIG. 38 illustrates the semiconductor device after the formation of the OPL, in accordance with some embodiments.

FIG. 39 illustrates the semiconductor device after the doping of the top doped region, in accordance with some embodiments.

FIG. 40 illustrates the semiconductor device after the removal of the OPL, in accordance with some embodiments.

FIG. 41 illustrates the semiconductor device after the formation of the interlayer dielectric layer, in accordance with some embodiments.

FIG. 42 illustrates the semiconductor device after the formation of the interlayer dielectric layer, in accordance with some embodiments.

FIG. 43 illustrates a block diagram of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter can be combined with elements of different embodiments.

In foundry technology, designing electrostatic discharge (ESD) protection devices requires addressing the diverse needs of typical input/output (I/O) configurations. These devices should meet stringent requirements to ensure robust protection against voltage spikes caused by ESD events while maintaining compatibility with the I/O types commonly used in advanced semiconductor technologies. The main categories of ESD devices for such applications include vertical bipolar transistors, lateral bipolar transistors, thyristors (also known as silicon-controlled rectifiers, SCRs), and power supply clamps. Each of these device types plays a distinct role in safeguarding sensitive circuits, depending on the application and performance requirements.

Vertical bipolar transistors are widely used in ESD protection circuits due to their ability to handle high current densities efficiently. Their vertically stacked structure allows current to flow perpendicularly to the plane of the substrate, enabling compact device layouts that can dissipate significant amounts of energy during an ESD event. These devices are typically implemented as NPN or PNP transistors, depending on the specific requirements of the circuit. Vertical bipolars are particularly advantageous in applications requiring high-speed protection and efficient integration into multi-layered semiconductor devices.

Lateral bipolar transistors offer an alternative approach, with current flowing parallel to the surface of the substrate. This lateral configuration provides greater flexibility in layout design and is often used in planar processes where space constraints or integration with other planar devices are priorities. Lateral bipolars are commonly employed in scenarios where high-speed response and precise control of the ESD protection mechanism are critical. Their planar nature also makes them well-suited for integration in standard CMOS technologies.

Thyristors, such as NPNP or PNPN configurations, are another component of ESD protection strategies. These devices operate as controlled switches that latch into a low-resistance state when triggered, allowing them to conduct large amounts of current away from sensitive circuit areas. Thyristors are especially effective for applications requiring high-current handling capabilities, making them suitable for protecting power-intensive I/O lines or circuits prone to high-voltage transients. The inherent current-limiting and latching characteristics of thyristors ensure that the device can respond effectively to sudden surges without impacting normal circuit operation.

Power supply clamps are one category of ESD protection devices, typically designed using circuits with wide field-effect transistors (FETs). These clamps act as voltage regulators during ESD events, providing a low-resistance path between power rails to shunt excess energy safely. The use of wide FETs in these clamps allows for higher current-carrying capacity, ensuring that power rails are effectively protected from overvoltage conditions. Power supply clamps are critical for safeguarding the integrity of the power distribution network within semiconductor devices, especially in high-density integrated circuits where stable power delivery is essential.

Together, these device types provide a comprehensive set of tools for addressing the diverse challenges posed by ESD protection in foundry technologies. By combining vertical and lateral bipolar transistors, thyristors, and power supply clamps, designers can create robust protection schemes tailored to the unique requirements of modern semiconductor applications, ensuring reliable performance and longevity of the devices.

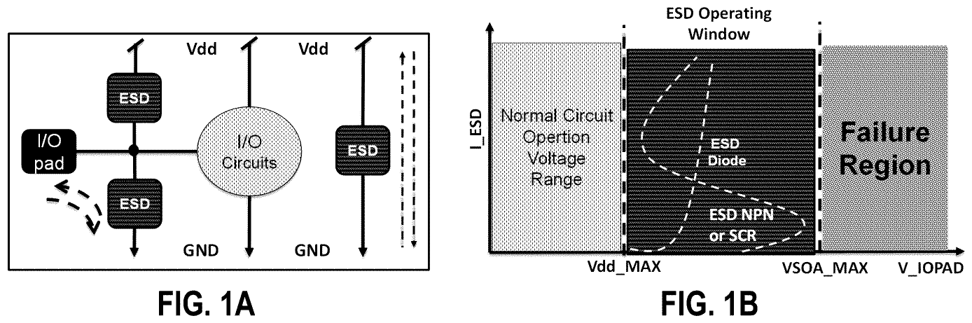

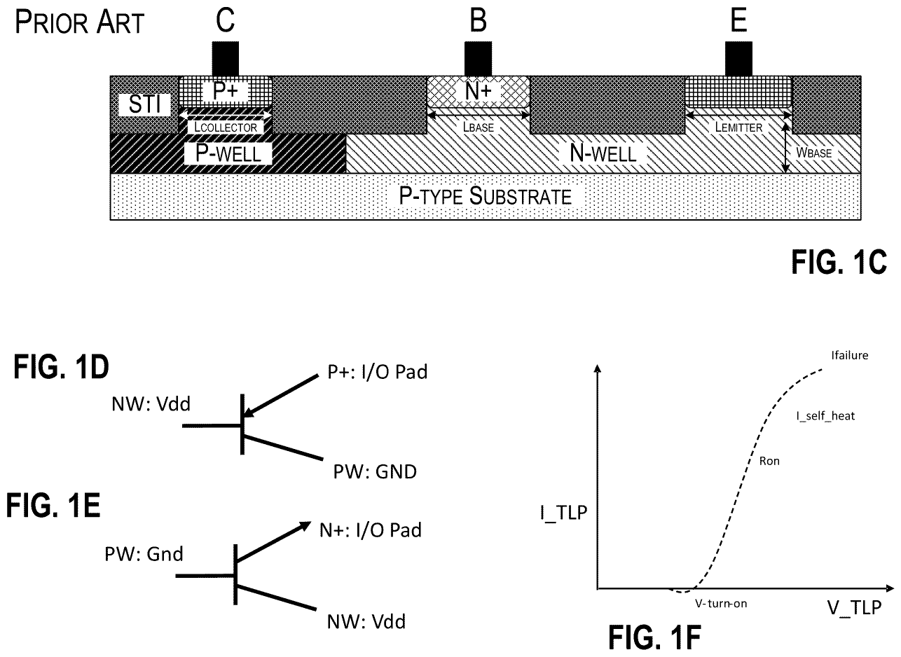

FIGS. 1A-1B illustrate schematically an ESD device operation during the normal circuit operation voltage range, ESD operating window during an ESD event, and the failure region. FIG. 1C illustrates a conventional planar semiconductor device with shallow trench isolation. FIGS. 1D-1E illustrate circuitry of the semiconductor device shown in FIG. 1C. FIG. 1F illustrates an I-V curve of the semiconductor device shown in FIG. 1C. A Planar CMOS shallow trench isolation (STI)-bound PNP transistor operates by enabling controlled current flow from the emitter to the collector through the base. This type of bipolar junction transistor (BJT) uses STI regions for electrical isolation, ensuring that the current paths are confined to specific regions within the transistor. The transistor is designed for compatibility with planar CMOS processes, making it suitable for high-density integrated circuits. In a PNP transistor, the emitter is a heavily doped P-type region that injects holes into the N-type base when a forward bias is applied across the base-emitter junction. The base, being lightly doped and thinner than the emitter, allows the majority of the injected holes to diffuse through it without significant recombination. These holes are then collected by the moderately doped P-type collector, completing the current flow through the transistor. The operation depends on maintaining the correct forward bias voltage across the base-emitter junction, typically requiring the base to be slightly negative relative to the emitter.

The STI regions are insulating trenches that surround the emitter, base, and collector. The trenches are filled with a dielectric material, such as silicon dioxide, to isolate the transistor electrically from adjacent devices in the circuit. The isolation prevents leakage currents and minimizes parasitic effects that could interfere with the transistor's operation. The STI ensures that the current flow remains within the intended regions of the transistor, enhancing its efficiency and reliability. Contacts for the emitter, base, and collector are positioned on the surface of the semiconductor device, allowing external connections to the transistor. The contacts are connected through interconnect layers, which are carefully aligned to the respective regions of the transistor. The STI provides a physical barrier, helping to ensure that these connections do not short-circuit or interfere with neighboring components.

The functionality of this transistor extends to its integration within CMOS processes, allowing it to coexist with other planar CMOS devices. The planar design, combined with STI isolation, enhances its performance by reducing parasitic capacitance and ensuring that the device operates effectively within the confines of a densely packed semiconductor layout. This configuration makes the STI-bound PNP transistor, or its NPN counterpart, a versatile choice for various applications, including analog circuits, mixed-signal designs, and ESD protection.

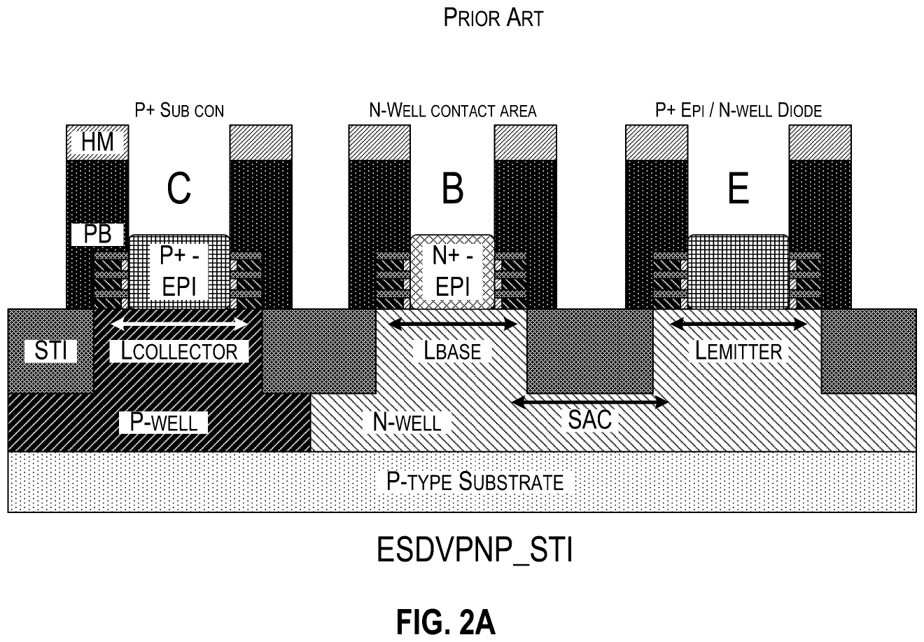

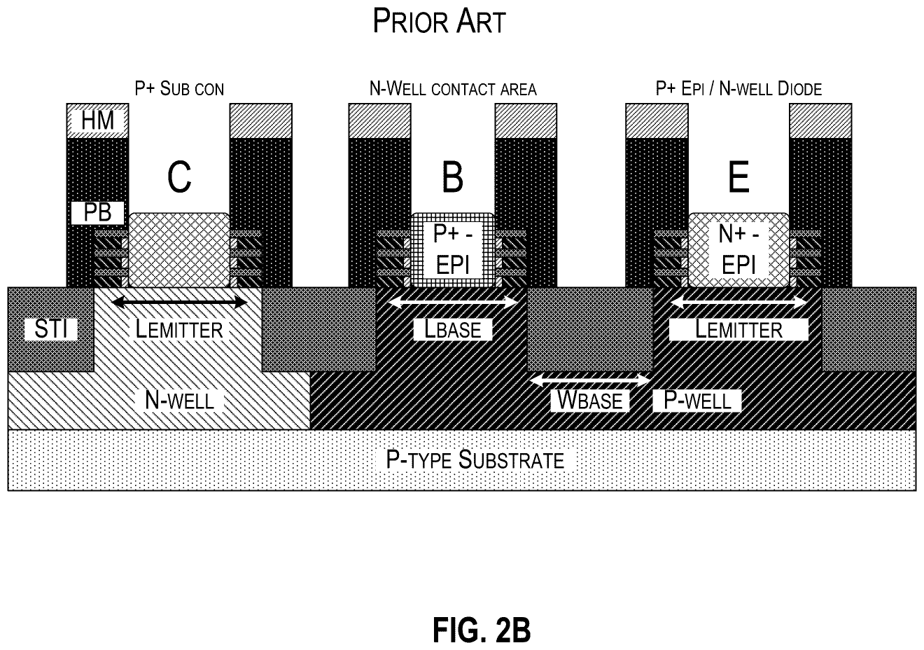

FIGS. 2A-2B illustrate conventional electrostatic discharge devices with shallow trench isolation. An ESD VPNP (Vertical PNP) and ESD VNPN (Vertical NPN) transistor with STI commonly referred to as ESDVPNP_STI and ESDVNPN_STI, are specialized bipolar junction transistors designed for electrostatic discharge (ESD) protection. Such devices leverage their vertical structure and STI isolation to efficiently handle high transient currents during ESD events while maintaining compactness and electrical isolation in semiconductor circuits.

The ESDVPNP_STI operates by facilitating current flow from a heavily doped P-type emitter, through a lightly doped N-type base, to a heavily doped P-type collector. During an ESD event, a sudden voltage spike forward-biases the base-emitter junction, allowing holes from the P-type emitter to be injected into the N-type base. The holes diffuse through the base and are collected by the P-type collector. The vertical configuration directs the current perpendicular to the plane of the substrate, which enables the device to conduct large amounts of current while minimizing the space required. The STI surrounding the emitter, base, and collector provides electrical isolation, ensuring that the current flow is confined to the intended path and does not interfere with adjacent devices.

Similarly, the ESDVNPN_STI operates with electrons as the primary charge carriers. In this case, a heavily doped N-type emitter injects electrons into a lightly doped P-type base when the base-emitter junction is forward-biased during an ESD event. The electrons traverse the base and are collected by the heavily doped N-type collector. The vertical current flow, combined with the isolation provided by STI, ensures efficient conduction and effective dissipation of the high transient currents caused by the ESD pulse. By electrically isolating the emitter, base, and collector from adjacent components, STI prevents leakage currents and parasitic interactions that could degrade the performance of the device. The isolation also allows the ESDVPNP_STI and ESDVNPN_STI to be integrated seamlessly into dense semiconductor layouts without compromising reliability.

During an ESD event, these devices act as current conduits, rapidly transitioning from a high-impedance state to a low-impedance state to safely dissipate the surge energy. The vertical configuration ensures that the conduction path can handle large currents efficiently, minimizing the risk of thermal or structural damage to the device. Once the ESD event subsides, the devices return to their high-impedance state, ready to protect the circuit again in future events. Both the ESDVPNP_STI and ESDVNPN_STI have the ability to manage high transient currents in a compact, isolated structure makes them suitable for use in advanced integrated circuits, ensuring robustness and reliability across a wide range of applications.

Disclosed is integrated multi-level electrostatic discharge (ESD) protection device for enhancing device robustness against the voltage spikes caused by static electricity. The stacked FET, or 3D FET, architecture addresses the challenge of maintaining area efficiency while improving performance and reducing power consumption in semiconductor devices. Unlike traditional planar FETs, where device miniaturization complicates the control of short-channel effects, stacked FETs vertically integrate multiple transistor layers on a single chip. This configuration save space and reduces the interconnect lengths and parasitic capacitance, enhancing signal transmission speed and decreasing power leakage. The nanosheet channels utilize thin, flat, ribbon-like semiconductors that allow for an effective control over the gate area compared to the 3D “fins” used in FinFETs. These nanosheets can be made wider than the fins, providing a higher drive current per footprint. The vertical stacking of several sheets in a single transistor also facilitates tuning the threshold voltage without the need for doping, reducing variability and enhancing performance consistency.

Precise alignment of nano-sheets in a stacked configuration ensures uniform electrical characteristics across all layers. Furthermore, the ESD protection circuits is designed to be robust enough to handle ESD stress without interfering with the normal operation of the CMOS device. Advanced lithography and etching techniques are used to construct the nanosheet channels and stack them accurately, while atomic layer deposition (ALD) and chemical vapor deposition (CVD) can be employed to form uniform, defect-free nano-sheets. The disclosed semiconductor device is especially suitable for applications where high reliability and density are paramount, such as in automotive electronics, aerospace, and high-performance computing environments. The enhanced control provided by nano-sheet channels results in improved device performance with reduced power consumption and heat generation, making the device ideal for the next generation of processors in both mobile and server applications. The integration of features such as stacked FETs and multi-level ESD protection not only tackles physical scaling challenges but also meets the growing demand for energy-efficient, high-performance electronic devices.

Accordingly, the teachings herein provide methods and systems of an electrostatic discharge device in stacked transistors with nanosheet channel structures. The techniques described herein may be implemented in a number of ways. Example implementations are provided below with reference to the following figures.

### Example Semiconductor Device with Electrostatic Discharge Device in Stacked Transistors with Nanosheet Channel Structure

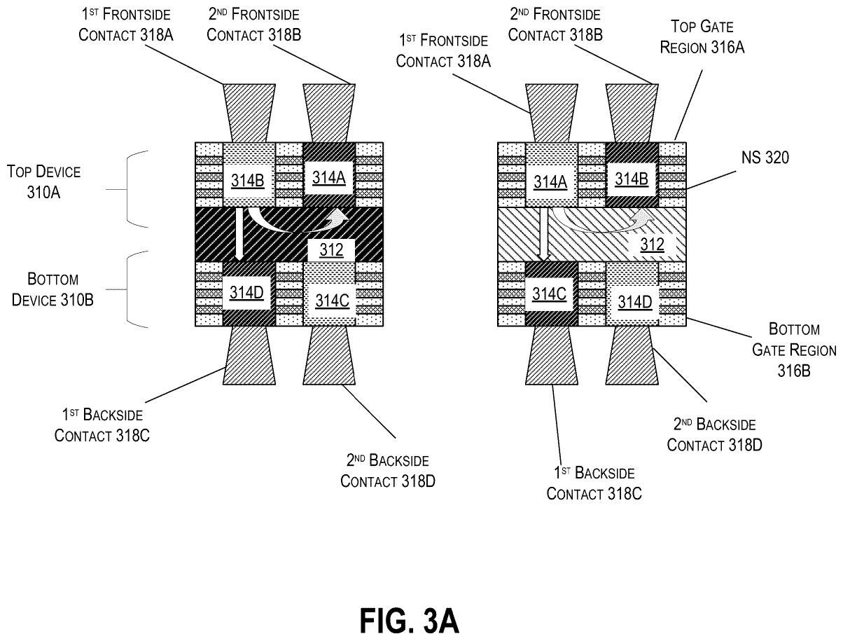

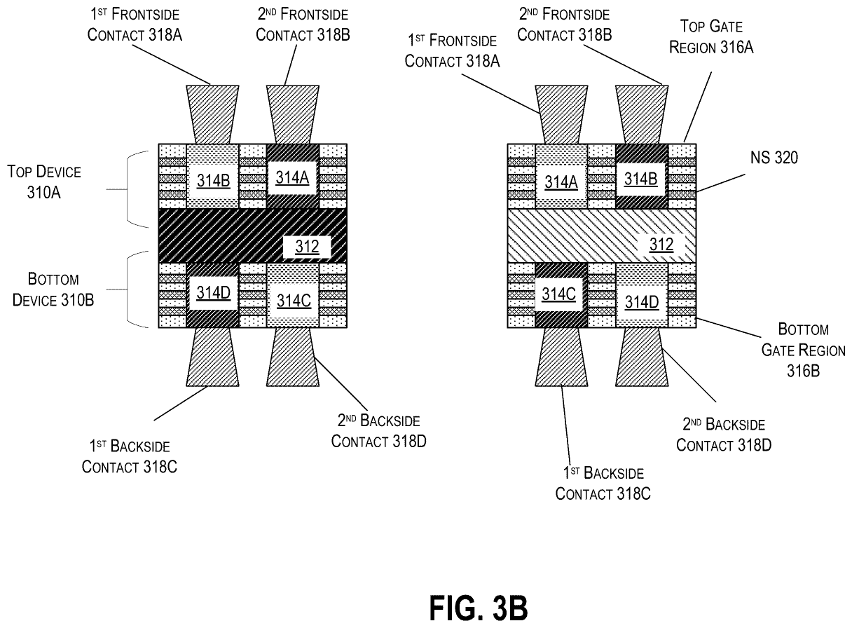

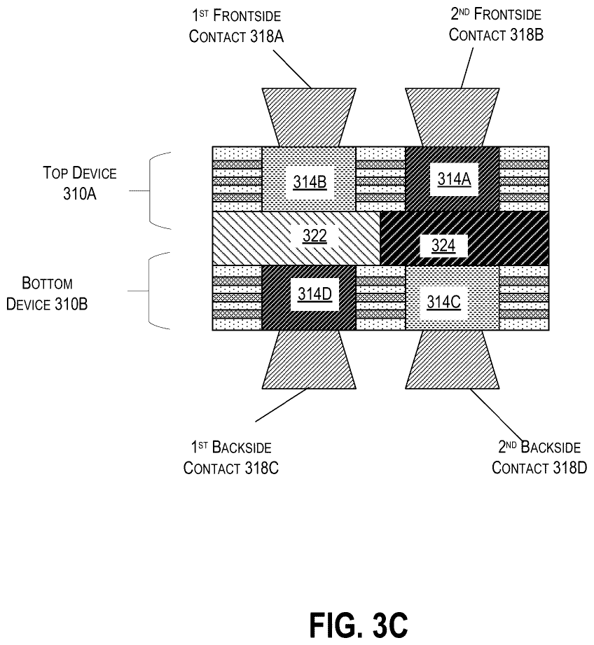

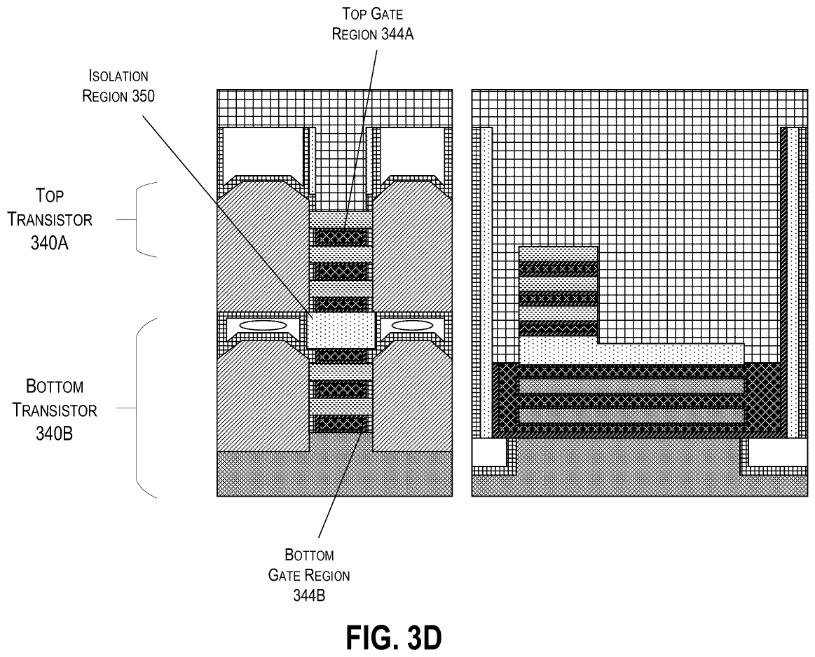

Reference now is made to FIGS. 3A-3C, which are simplified cross-section views of a semiconductor device, consistent with illustrative embodiments. FIG. 3A illustrates a stacked field-effect transistor electrostatic discharge (FET ESD) vertical/lateral diodes, in accordance with some embodiments. The semiconductor device can include a passive device and a logic device. The components include a top device 310A, a bottom device 310B, a well region, gate regions, and doped regions.

The top device 310A can be structured with a top N-type doped region 314A, a top gate region 316A, and a first frontside contact 318A. The top N-type doped region 314A is a semiconductor area that has been intentionally infused with impurities, or “doped,” to create an excess of electrons (N-type), enabling it to conduct electricity. The top gate region 316A serves as a control element, modulating current flow through the top device 310A by applying an electric field across the top N-type doped region 314A. The gating capability allows for selective control over current passage, which is valuable in applications that require switching or modulation of signals. The first frontside contact 318A on the top device 310A provides a connection point on the upper surface of the semiconductor device, allowing the top device 310A to interface with external circuitry.

The top device 310A can be structured with a top P-type doped region 314B and a second frontside contact 318B. The top P-type doped region 314B is a semiconductor area that has been intentionally infused with impurities, or “doped,” to create an excess of holes (P-type), enabling it to conduct electricity. The top gate region 316A serves as a control element, modulating current flow through the top device 310A by applying an electric field across the top P-type doped region 314B. The gating capability allows for selective control over current passage, which is valuable in applications that require switching or modulation of signals. The second frontside contact 318B on the top device 310A provides a connection point on the upper surface of the semiconductor device, allowing the top device 310A to interface with external circuitry.

The bottom device 310B is composed of a bottom P-type doped region 314C, a bottom gate region 316B, and a first backside contact 318C. The bottom P-type doped region 314C is created through doping to control the type and flow of charge carriers. The bottom gate region 316B, positioned adjacent to the bottom P-type doped region 314C, enables control over the current in the bottom device 310B through an applied electric field, facilitating precise modulation of current flow. The first backside contact 318C allows for connection through the lower surface of the semiconductor device, providing an alternate pathway for current flow and enabling more efficient layout and integration within larger circuit structures. Such an arrangement of the first frontside contact 318A and the first backside contact 318C provides flexible options for routing and integrating the device into various circuit designs.

The bottom device 310B is composed of a bottom N-type doped region 314D and a second backside contact 318D. The bottom N-type doped region 314D is created through doping to control the type and flow of charge carriers. The bottom gate region 316B, positioned adjacent to the bottom N-type doped region 314D, enables control over the current in the bottom device 310B through an applied electric field, facilitating precise modulation of current flow. The second backside contact 318D allows for connection through the lower surface of the semiconductor device, providing an alternate pathway for current flow and enabling more efficient layout and integration within larger circuit structures. Such an arrangement of the second frontside contact 318B and the second backside contact 318D provides flexible options for routing and integrating the device into various circuit designs.

A well region 312 electrically connects the top device 310A and the bottom device 310B forming a continuous path for current flow between them. The well region 312 acts as an intermediary layer that can be either an in situ-doped semiconductor layer, e.g., it is doped during fabrication to the desired conductivity, or an implant layer where dopants are implanted after the initial layer formation. The well region 312 supports stable electrical connection between the top device 310A and the bottom device 310B, ensuring consistent performance. In some embodiments, the well region 312 is an N-well or a P-well, which is lightly doped with N-type impurities or P-type impurities, respectively.

The top device 310A and the bottom device 310B can each include nanosheet channels in a gate all around structure, NS 320, that extend horizontally across a gate channel. NS 320 are ultra-thin, planar gate structures that provide control over current flow through the gate channel, improving the switching speed and electrical efficiency of the device. Horizontal extension of the NS 320 allows for improved layout flexibility, helping to minimize the device footprint and enable high-density integration within semiconductor circuits.

The described semiconductor device showcases a design that integrates multiple functional elements within a single architecture, and features both vertical and lateral devices within the same structure, operating in parallel. This dual configuration enhances the device's versatility, allowing it to manage applications that require both high voltage efficiency and fast switching capabilities. The well region 312 can be either an in situ-doped intermediate semiconductor layer or an implant layer. Each method offers distinct advantages; in situ doping achieves a uniform distribution of dopants during the layer's growth, while implantation allows for precise localized doping adjustments after the layer formation. This flexibility in the doping approach enables precise control over the device's electrical properties, optimizing it for specific performance requirements.

Additionally, the semiconductor device includes input and output contacts where at least one of the top or bottom devices functions as a bipolar junction transistor (BJT). Both contacts are situated at the same metallization level. Such a configuration simplifies the interconnection process, reduces the layout complexity, and helps improve signal integrity by minimizing parasitic resistances and capacitances. Furthermore, the device can form a diode configuration where the input and output contacts are positioned either on opposite sides or the same side of the device. This allows for integration into different circuit topologies and supports both common-anode and common-cathode configurations, depending on the specific requirements of the application.

The semiconductor device can incorporate a set of nanosheet channels that are adjacent to an active device layer and are electrically connected to it, while the top gate regions and the bottom gate regions next to this layer are electrically isolated. Such a structure ensures that the nanosheet channels can control the current through the active layer, and the isolation of the gate regions prevents electrical interference, thereby enhancing the operational stability and efficiency of the device.

Furthermore, the semiconductor device includes distinct doping types for the top and bottom regions. The P-N configuration across the top and bottom regions, in conjunction with the well region 312 that electrically connects them, establishes a complementary charge system, allowing for smooth current flow and supporting diverse applications that require both P-type and N-type characteristics.

In some embodiments, the passive semiconductor device can function as a vertical ESD diode protecting sensitive circuits from high-voltage spikes associated with ESD events. The vertical ESD diode structure provides a vertically oriented pathway for current flow, allowing it to rapidly conduct excess charge away from vulnerable circuit areas. In this configuration, the device can take one of two forms, either a P+/P-Well/N+ diode, or a P+/N-Well/N+ diode.

In the P+/P-Well/N+ diode configuration, the device is constructed of a P+ doped region, a P-well (PW) region, and an N+ doped region. The P+ region, located at the top of the device, is highly doped with positive charge carriers (holes), while the N+ region, positioned at the bottom, is highly doped with negative charge carriers (electrons). The P-well region, which is lightly doped with P-type impurities, serves as an intermediary layer between the P+ and N+ regions. The structure creates a diode with a strong P-N junction between the P-well and N+ region, allowing it to act as a unidirectional current path that only becomes conductive under certain voltage conditions. When an ESD event occurs, the diode becomes forward-biased, allowing it to conduct current vertically through the structure, thereby safely dissipating the excess charge to protect the connected circuitry. The P+/PW/N+ structure is advantageous in scenarios requiring a lower trigger voltage, as the P-well provides a closer potential alignment with the P+ region, allowing for a faster response during an ESD event.

Alternatively, the semiconductor device can be configured as a P+/N-Well/N+ diode (P+/NW/N+ diode). In this design, the top P+ doped region is paired with an N-well (NW) region, which is lightly doped with N-type impurities, positioned between the P+ and N+ regions. The N-well provides a different junction characteristic compared to the P-well, which affects the diode's breakdown voltage and response time. In this case, the P+/NW/N+ structure creates a P-N junction between the P+ region and the N-well, providing a more defined potential barrier and a higher threshold for conduction. When an ESD event generates a high enough voltage, the diode becomes forward-biased, allowing current to flow through the device and dissipate the ESD pulse.

Both configurations, whether P+/PW/N+or P+/NW/N+, provide effective ESD protection by offering a low-resistance path for current when triggered, allowing the device to shunt damaging surges away from sensitive components. The vertical orientation of these ESD diodes enables efficient integration within multi-layer or compact designs, supporting a high degree of layout flexibility while delivering reliable ESD protection. The choice between a P-well or N-well layer allows for tuning of the trigger and breakdown voltages, enabling the passive device to be tailored to specific voltage and protection requirements in various semiconductor applications.

The semiconductor device features an intricate architecture that combines various components and functionalities to achieve high performance and versatility in electronic applications. The semiconductor device incorporates both a vertical and a lateral device within the same structural framework, arranged in parallel. Such an arrangement allows the device to exploit the benefits of both orientations, enhancing functionality and performance. The semiconductor device includes input and output contacts, with at least one of the top or bottom devices functioning as a bipolar junction. The setup is capable of effectively amplifying current, making it suitable for high-frequency and high-power applications. The bipolar junction, with both input and output contacts located at the same metallization level, simplifies the manufacturing process and enhances reliability by minimizing interconnect complexity. Furthermore, the semiconductor device can also form a diode, with the input and output contacts positioned either on opposite sides or the same side of the semiconductor device. Additionally, the semiconductor device features a set of nanosheet channels adjacent to and electrically connected with an active device layer. The top and bottom gate regions, which are adjacent to the active layer, are electrically isolated. In some embodiments, the well region is electrically connected to the top P-type doped region, the top N-type doped region, the bottom P-type doped region, and the bottom N-type doped region. The extensive interconnection supports transistor operation, allowing for different types of transistor configurations and functionalities within a single semiconductor device.

FIG. 3B illustrates stacked FET ESD diagonal bipolars, in accordance with some embodiments. In some embodiments, the semiconductor device can be configured as a diagonal NPN transistor that includes P+P-well contacts. Alternatively, the semiconductor device can be configured as a diagonal PNP transistor featuring N+N-well contacts. These configurations indicate the orientation and doping characteristics of the transistor, where “diagonal” refers to the arrangement of the semiconductor structure, enhancing electrical properties such as current flow or breakdown voltage by altering the path through which carriers travel within the device. In the diagonal NPN configuration, the P+ P-well contacts are utilized, which are highly doped p-type contacts within an n-type well, enhancing the emitter efficiency and reducing the base resistance. This setup is typically used to improve the speed and performance of the transistor in switching applications. Conversely, the diagonal PNP configuration uses N+ N-well contacts, involving highly doped n-type contacts within a p-type well, which can be advantageous for applications requiring high voltage tolerance and thermal stability. This arrangement might be preferred in power applications where higher voltage handling and thermal performance are important.

FIG. 3C illustrates stacked FET ESD vertical/lateral silicon-controlled rectifier, in accordance with some embodiments. In some embodiments, the semiconductor device combines stacked FETs with ESD protection using both vertical and lateral silicon-controlled rectifiers (SCRs). Such a configuration integrates the strengths of both FETs and SCRs to offer a comprehensive ESD protection mechanism ideal for complex, high-density semiconductor applications. The use of stacked FETs in this design involves layering multiple transistor gates vertically within a compact device footprint. The vertical stacking helps in managing higher voltages and distributing power efficiently for shielding sensitive components from ESD impacts. The vertical arrangement of the FETs helps conserve valuable chip space while enhancing electrical characteristics such as reduced capacitance and resistance, which are vital for the overall performance of the semiconductor. In some embodiments, two well regions, e.g., a first well region 322 and a second well region 324, are connected to each other.

Incorporating SCRs in both vertical and lateral orientations within the same device structure enhances the ESD protection capability. Vertical SCRs can be employed for their robust high voltage handling abilities to protect against direct and powerful ESD strikes that can immediately damage internal circuitry. Conversely, lateral SCRs are effective for their quicker response to lower-energy ESD events, providing a first line of defense by managing more frequent, lesser impacts. By integrating these technologies, the semiconductor device achieves a dual-layered ESD protection scheme that not only guards against a broad spectrum of ESD energies but also improves the device's durability and reliability. This setup ensures that the device remains stable and functional even in environments where ESD exposure poses a significant risk, thereby extending the operational lifespan and performance stability of the semiconductor device in challenging conditions. FIG. 3D illustrates a FET region of the semiconductor device. The FET region can include a top transistor 340A over a bottom transistor 340B, separated by an isolation region 350, top gate regions 344A and bottom gate regions 344B.

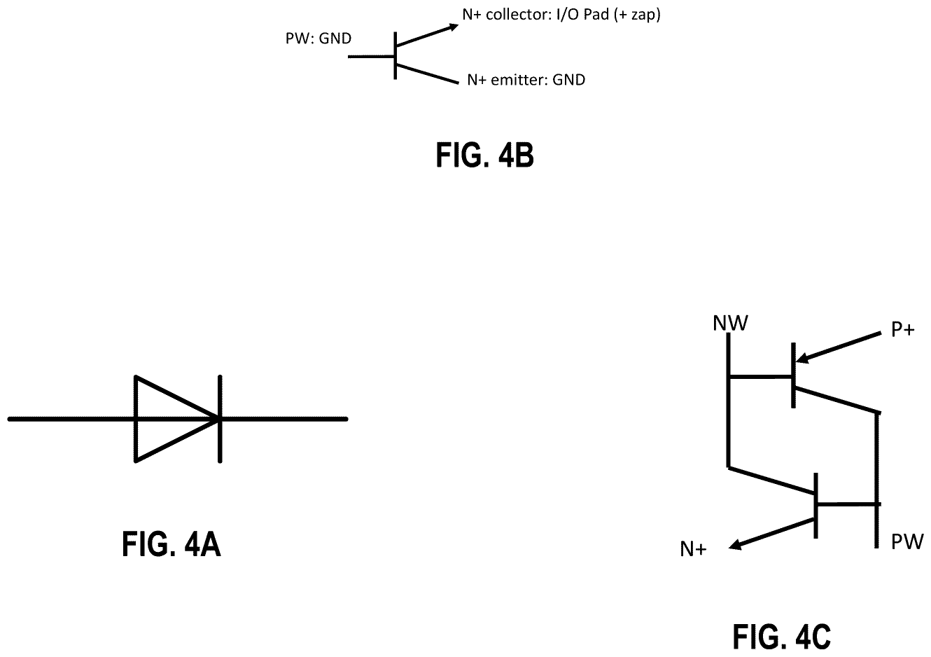

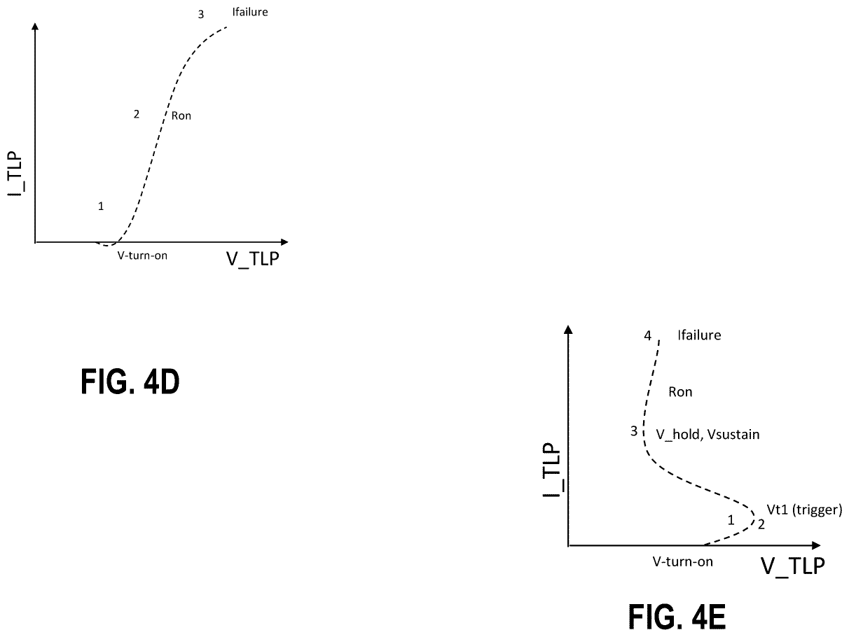

FIGS. 4A-4C illustrate circuitry representing the semiconductor device of FIGS. 3A-3C, respectively. FIG. 4D illustrates an I-V diagram of the semiconductor device of FIG. 3A, and FIG. 4E illustrates an I-V diagram of the semiconductor device of FIGS. 3B-3C. The semiconductor device's regions of operation can be divided into distinct phases: leakage or pre-turn-on, trigger or turn-on 402, holding or sustaining 410, and failure 406. The leakage or pre-turn-on region is the initial phase of the device's operation when it is in a high-impedance state. During this phase, the device conducts only a minimal leakage current, which can be negligible and does not interfere with normal circuit operation. The behavior ensures that the device remains passive and non-disruptive during regular operation, activating only when necessary. The leakage region is influenced by factors such as the quality of the junctions, doping concentrations, and the surrounding isolation structures.

The trigger or turn-on region, which occurs at trigger voltage 408, marks the transition of the device from the high-impedance state to a low-impedance conductive state. This phase occurs when the voltage across the device exceeds the trigger voltage. The trigger voltage is a parameter that defines the threshold at which the device activates to conduct significant current. During this phase, the device begins to conduct current rapidly, responding to an external stimulus such as an ESD event or overvoltage condition. The speed and reliability of this transition are critical for effective protection and performance.

The holding or sustaining region represents the stable operational phase of the device after it has been triggered. In this phase, the device remains in a low-impedance state, conducting current efficiently to dissipate excess energy. The holding or sustaining voltage, often lower than the trigger voltage, ensures that the device remains conductive as long as the external current source persists. This phase is characterized by parameters such as Ron 404, the on-resistance of the device, which determines the voltage drop and power dissipation during conduction. A low Ron value is desirable to minimize energy loss and heat generation. This region is crucial for ensuring the safe dissipation of transient energy without compromising the device's structural integrity.

The failure region occurs when the device exceeds its operational limits, such as the maximum voltage or current it can handle. This phase represents the breakdown or destruction of the device, often due to excessive energy input that surpasses the material or structural limits. In addition to these regions, the device's behavior is influenced by its load capacitance, which represents the capacitance seen by the device in the circuit. Load capacitance affects the device's response time, energy dissipation, and overall performance. A high load capacitance can slow down the device's response, potentially impacting its ability to protect the circuit effectively during fast transients. As can be seen, the I-V relationship of the semiconductor device of FIG. 3A is almost linear until the device breaks. The I-V relationship for the diagonal bipolars, e.g., FIG. 3B, and the vertical/lateral SCR, e.g., FIG. 3C, is similar to each other.

### Example Fabrication of A Semiconductor Device with Electrostatic Discharge Device in Stacked Transistors with Nanosheet Channel Structure

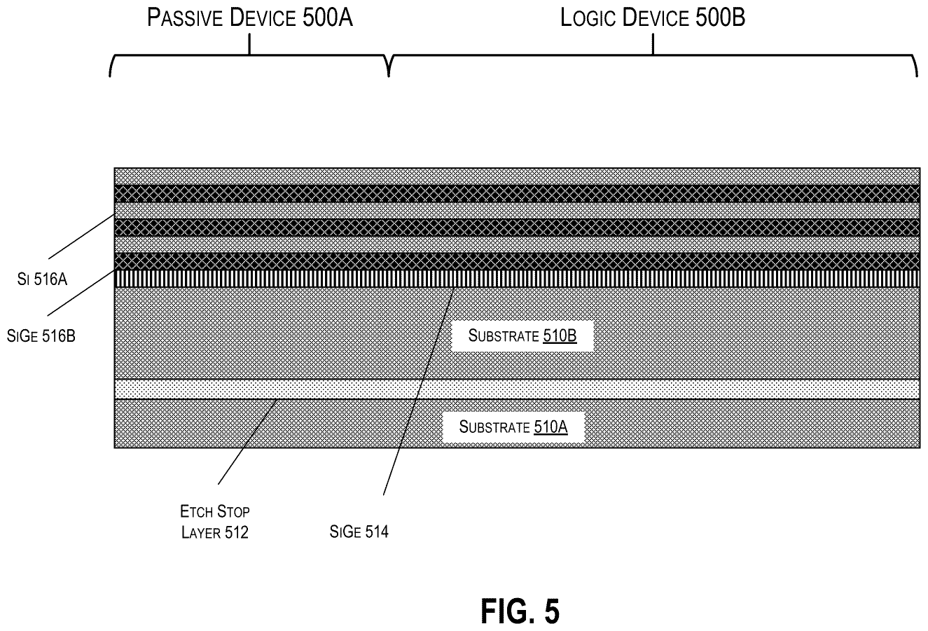

With the foregoing description of an example semiconductor device, it may be helpful to discuss an example process of manufacturing the same. To that end, FIGS. 5-43 illustrate various acts in the manufacture of a semiconductor device, consistent with illustrative embodiments.

Reference now is made to FIG. 5, which is a simplified cross-section view of a semiconductor device, after the preparation of the first half of the sheet stack, consistent with an illustrative embodiment. The semiconductor can include a passive device 500A and a logic device 500B, which include a first substrate 510A, an etch stop layer 512, a second substrate 510B, a layer of high-Ge SiGe 514, and alternating layers of Si 516A and SiGe 516B.

In the illustrative example depicted in FIG. 5, the semiconductor device is depicted as being on silicon as the first substrate 510A and the second substrate 510B, while it will be understood that other types as the first substrate 510A and the second substrate 510B can be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the first substrate 510A and the second substrate 510B can include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

In various embodiments, the etch stop layer 512 is formed between the first substrate 510A and the second substrate 510B. The etch stop layer 512 can be a thin layer of material incorporated into the structure of the semiconductor device to provide a selective barrier against etching processes, preventing further removal of underlying materials during fabrication. The etch stop layer 512 can enable precise control over the etching depth and help define the desired device dimensions. The etch stop layer 512 can further provide a stopping point for the etching process, ensuring that specific layers or regions are not etched beyond a certain point, leading to accurate patterning and control of critical features. The etch stop layer 512 can create a distinct separation between different layers or components within the device structure, and prevent the undesired etching of underlying layers or materials, enabling the creation of complex, multi-layered structures with well-defined interfaces and boundaries. In some embodiments, the etch stop layer 512 acts as a protective barrier for sensitive or delicate materials to shield such materials from aggressive etchants, preventing damage or degradation during subsequent fabrication steps.

In some embodiments, prior to forming the etch stop layer 512, the first substrate 510A and/or the second substrate 510B is prepared by cleaning and removing any impurities or oxide layers. The etch stop layer 512 is deposited onto the first substrate 510A using techniques such as chemical vapor deposition (CVD), physical vapor deposition (PVD), or atomic layer deposition (ALD). In an embodiment, a photoresist can be applied, exposed to a patterned mask, developed, and used as a protective layer to define the etch stop regions. The etch stop layer 512 can then be selectively etched, stopping at a predetermined depth, while protecting the underlying layers. After the etching process, the remaining photoresist can be removed through stripping techniques. While in some embodiments, SiGe is used to form the etch stop layer 512, in some embodiments, silicon nitride (SiN), silicon oxide (SiO2), or silicon oxynitride (SiON) can be used as the etch stop layer 512.

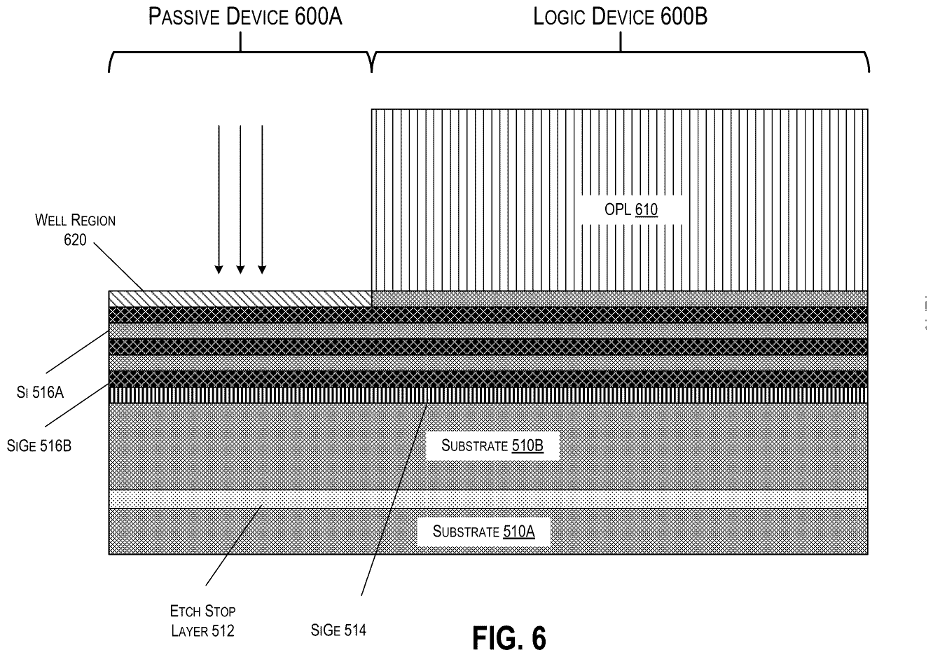

FIG. 6 illustrates the semiconductor device after the implantation of the passive device, in accordance with some embodiments. In some embodiments, an organic planarization layer, OPL 610, is formed over the logic device 600B. The passive device 600A is implanted to form an N-well or a P-well., e.g., well region 620.

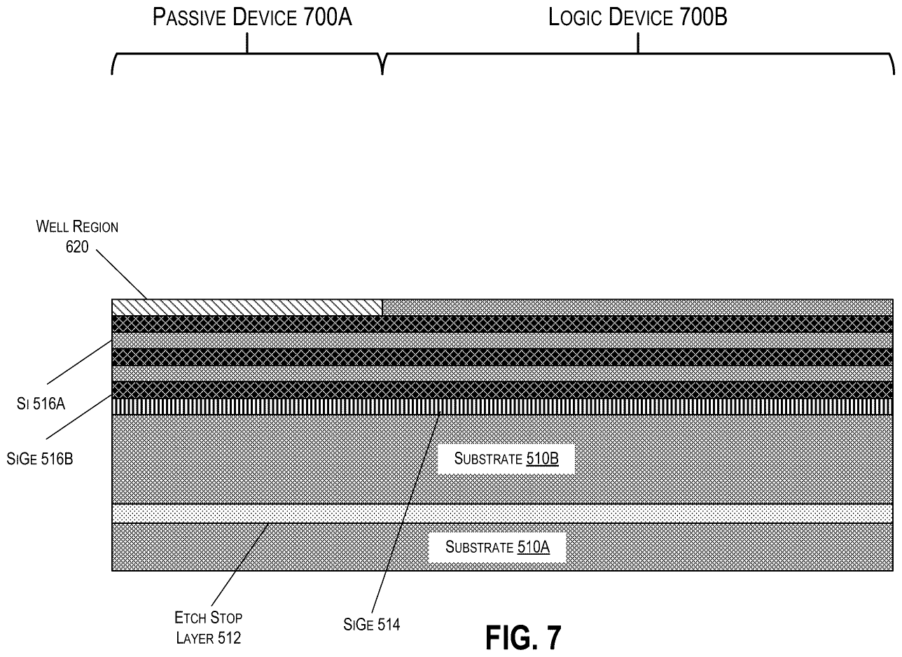

FIG. 7 illustrates the semiconductor device after the removal of the OPL, in accordance with some embodiments. In some embodiments, the OPL is removed, e.g., stripped.

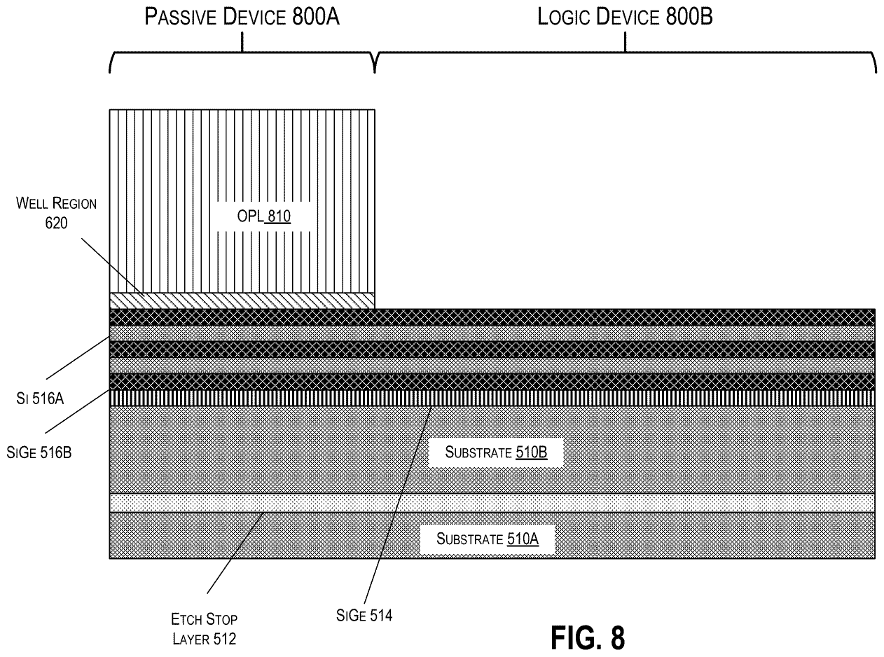

FIG. 8 illustrates the semiconductor device after the formation of the OPL, in accordance with some embodiments. In some embodiments, an OPL 810 is formed over the passive device 800A and the uppermost layer of Si is removed from the logic device 800B.

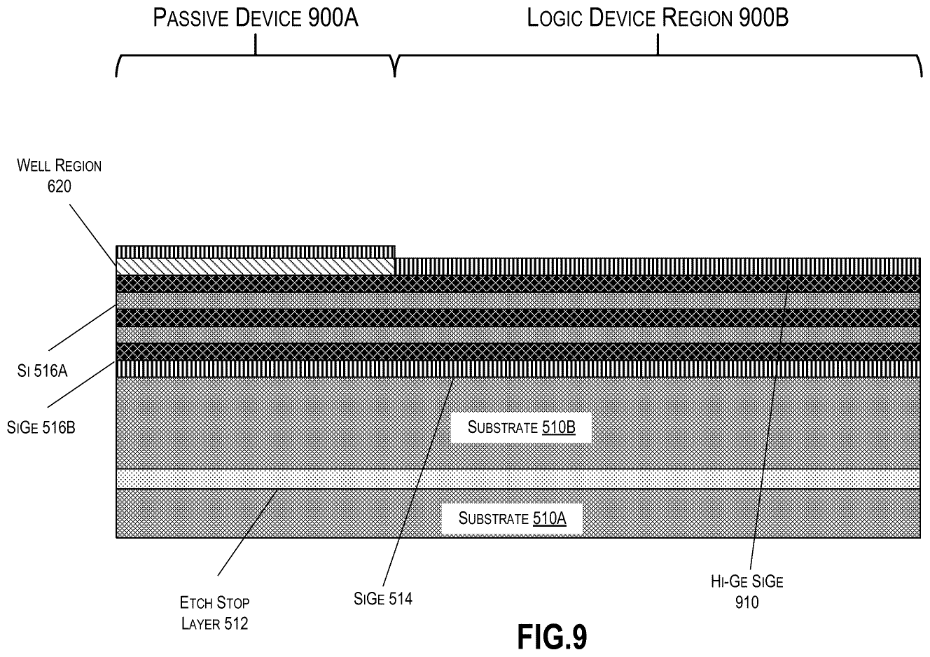

FIG. 9 illustrates the semiconductor device after the formation of a high-Ge SiGe layer, in accordance with some embodiments. In some embodiments, the OPL is removed and a layer of high-Ge SiGe 910 is formed over the passive device 900A and the logic device 900B.

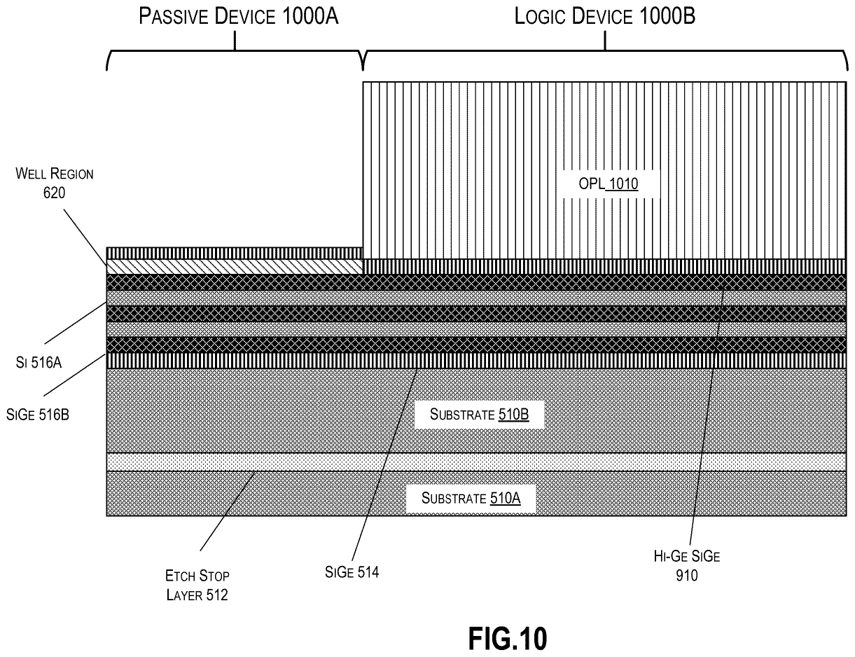

FIG. 10 illustrates the semiconductor device after the removal of portions of the high-Ge SiGe layer, in accordance with some embodiments. In some embodiments, an OPL 1010 is formed over the logic device 1000B and the high Ge-SiGe layer is removed from the passive device 1000A.

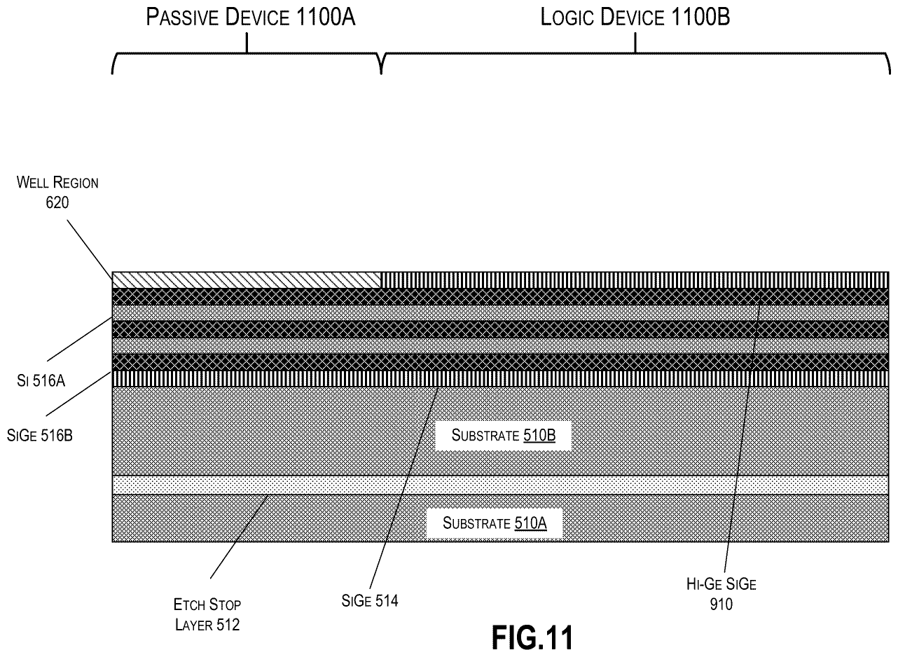

FIG. 11 illustrates the semiconductor device after the removal of organic planarization layer, in accordance with some embodiments. In some embodiments, the OPL is removed from the semiconductor device.

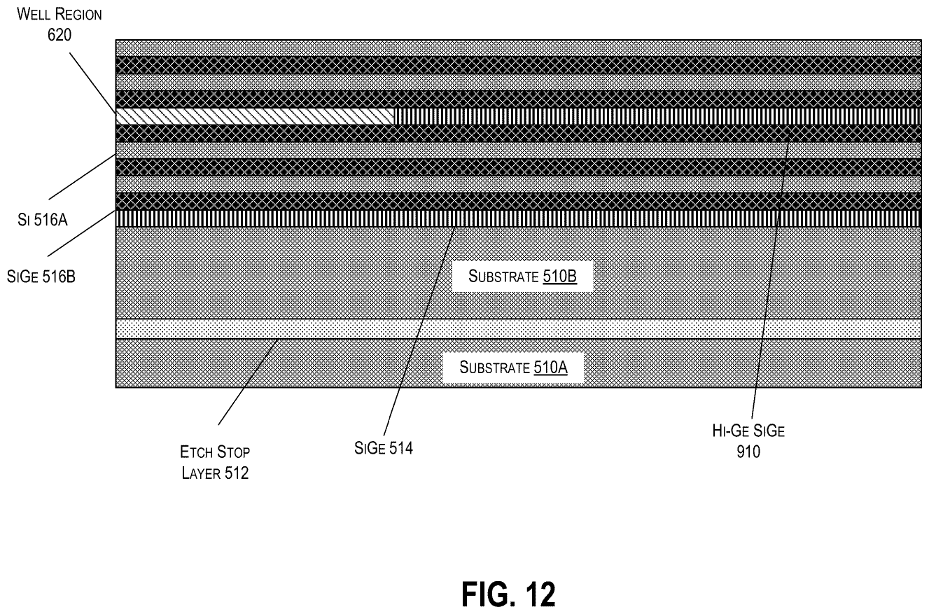

FIG. 12 illustrates the semiconductor device after the formation of the second half of the nanosheet stack, in accordance with some embodiments. In some embodiments, additional layers of Si and SiGe are formed over the semiconductor device.

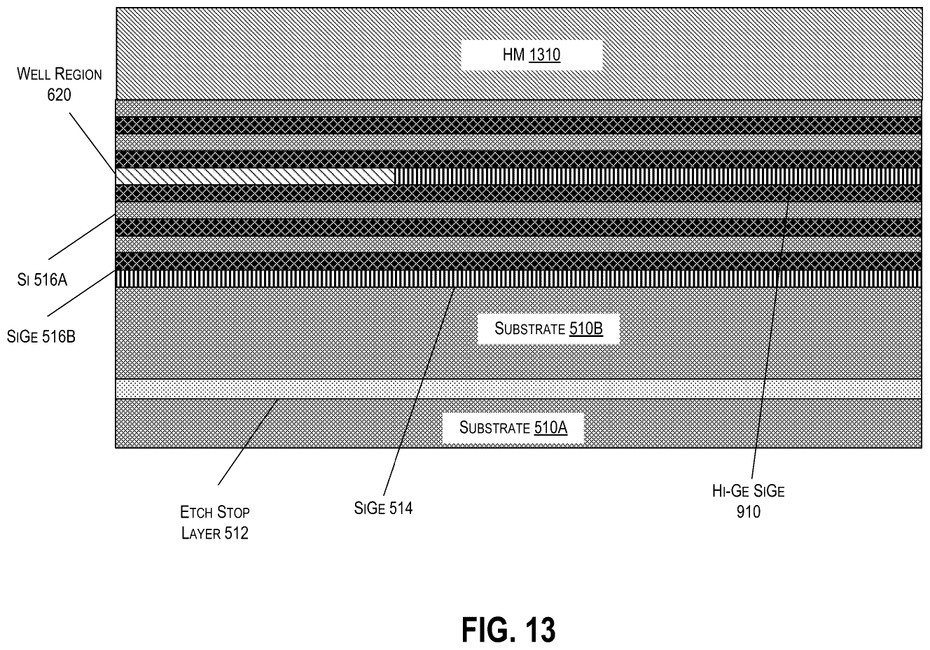

FIG. 13 illustrates the semiconductor device after the formation of hard masks, in accordance with some embodiments. In some embodiments, a hard mask, HM 1310, is formed over the semiconductor device.

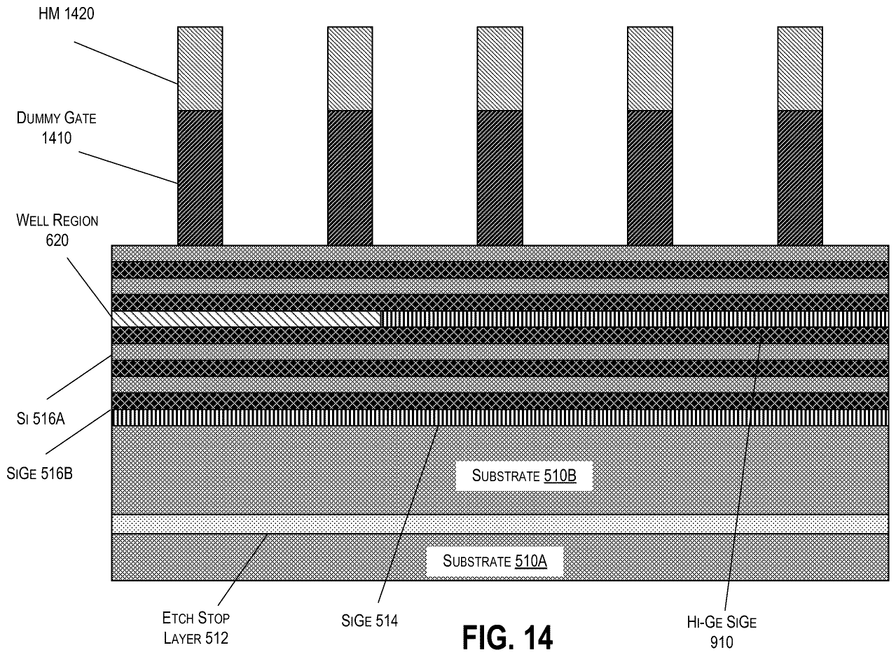

FIG. 14 illustrates the semiconductor device after the formation of dummy gates, in accordance with some embodiments. In some embodiments, stacks of dummy gates 1410 and hard masks, HM 1420, are formed over the semiconductor device.

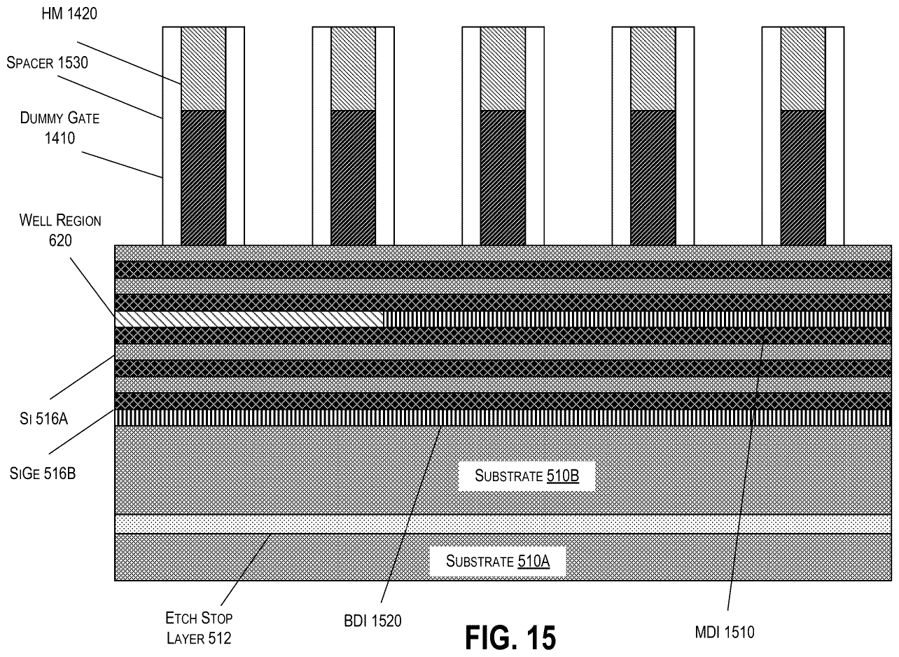

FIG. 15 illustrates the semiconductor device after the removal of the high-Ge SiGe layer, in accordance with some embodiments. In some embodiments, the high-Ge SiGe layer is removed and replaced by a middle dielectric interlayer, MDI 1510, and a bottom interlayer dielectric, BDI 1520. A spacer 1530 can be formed over the sidewalls of the stacks of dummy gates 1410 and HM 1420.

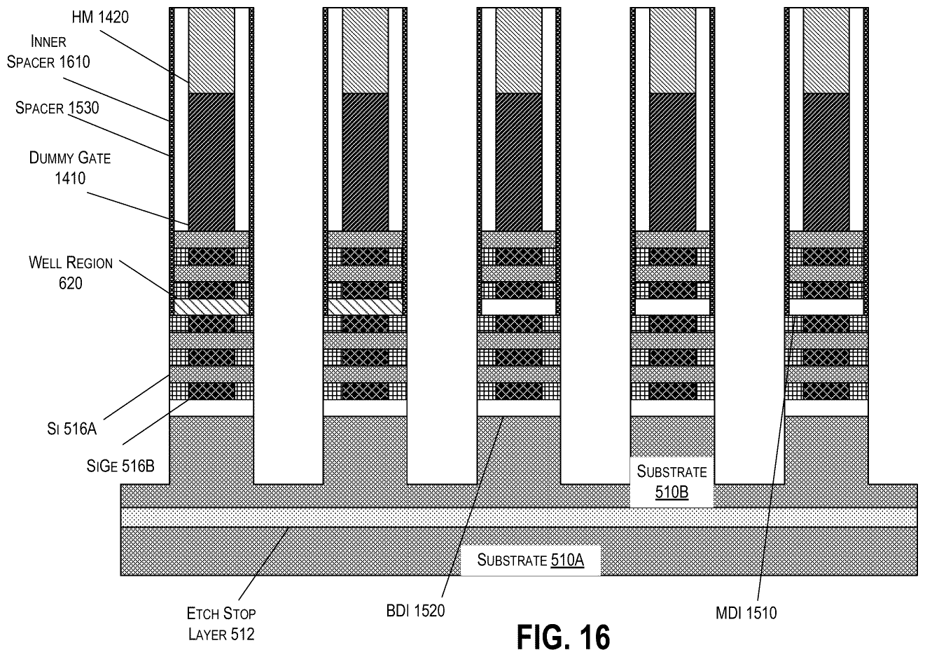

FIG. 16 illustrates the semiconductor device after the formation of the inner spacer and recession of the nanosheet, in accordance with some embodiments. In some embodiments, the top nanosheet are recessed and the SiGe layer are indented. An inner spacer 1610 is formed over the sidewalls of the stacks of dummy gates 1410 and HM 1420.

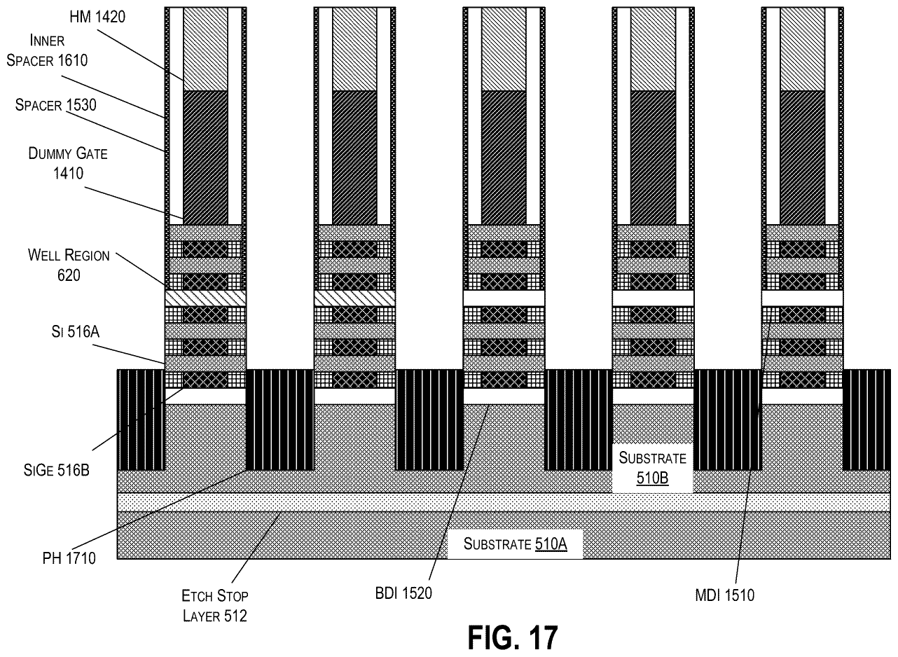

FIG. 17 illustrates the semiconductor device after the formation of the sacrificial placeholders, in accordance with some embodiments. In some embodiments, sacrificial placeholders, PH 1710, are formed between the stacks of dummy gates 1410 and HM 1420.

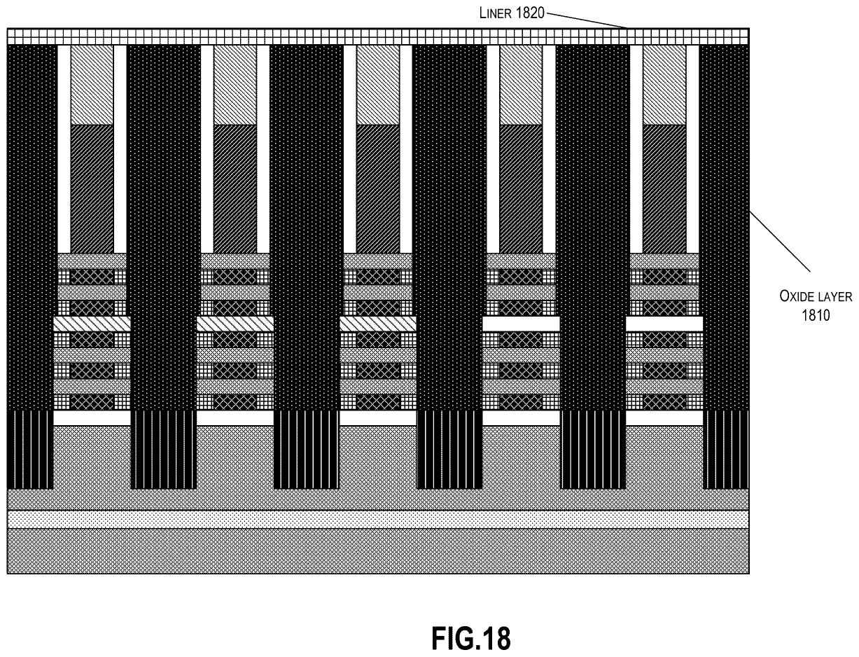

FIG. 18 illustrates the semiconductor device after the formation oxide backfill, in accordance with some embodiments. In some embodiments, an oxide layer 1810 is formed between the stacks followed by formation of a liner 1820.

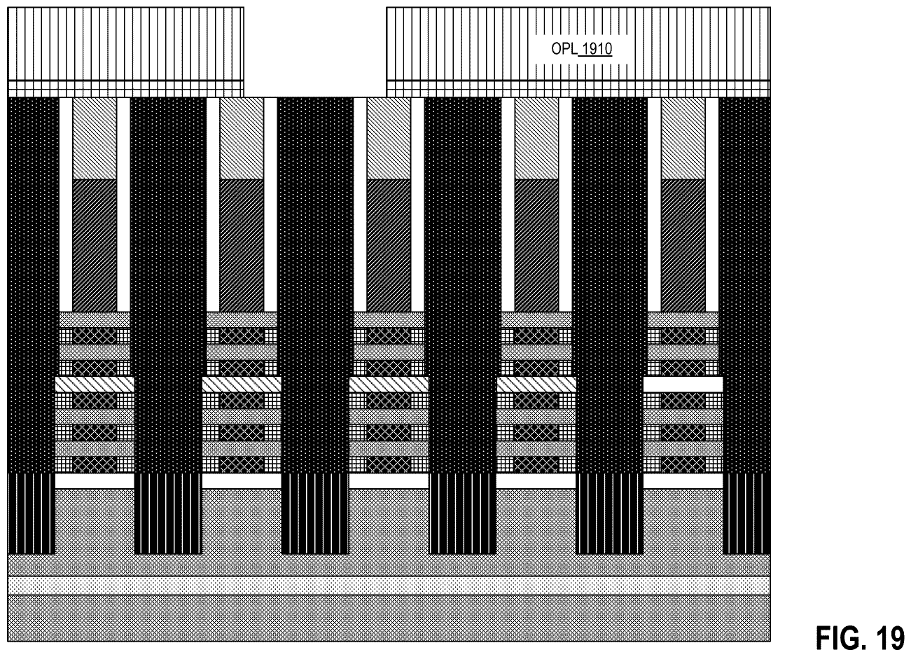

FIG. 19 illustrates the semiconductor device after the patterning of the frontside of the semiconductor device, in accordance with some embodiments. In some embodiments, an OPL 1910 is formed to protect the NFET. Portions of the frontside of the semiconductor device are patterned to remove the OPL 1910 and the liner 1820.

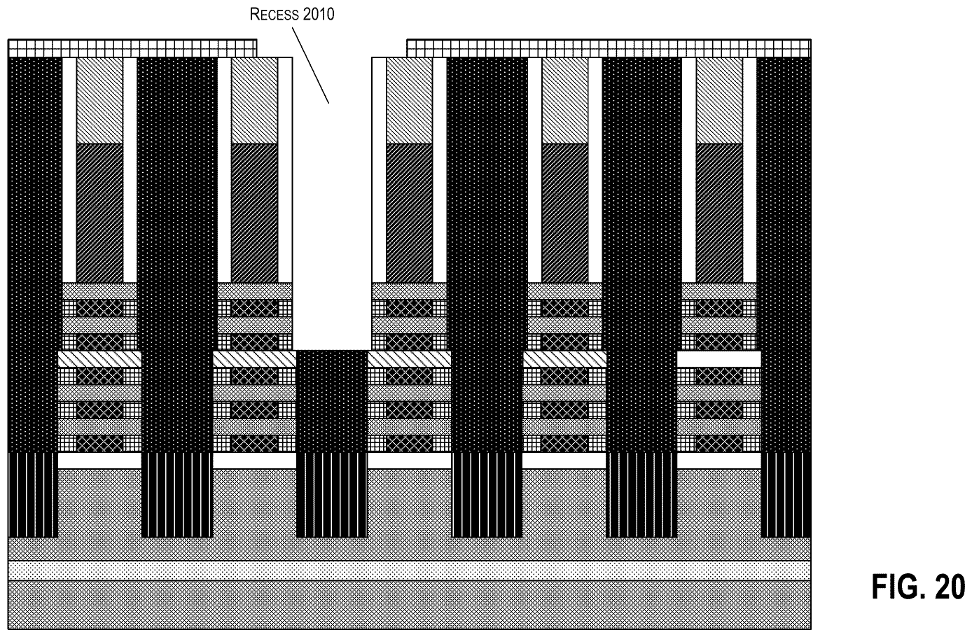

FIG. 20 illustrates the semiconductor device after the removal of the OPL, in accordance with some embodiments. In some embodiments, the OPL 1910 and the oxide layer 1810 are removed to form a recess 2010.

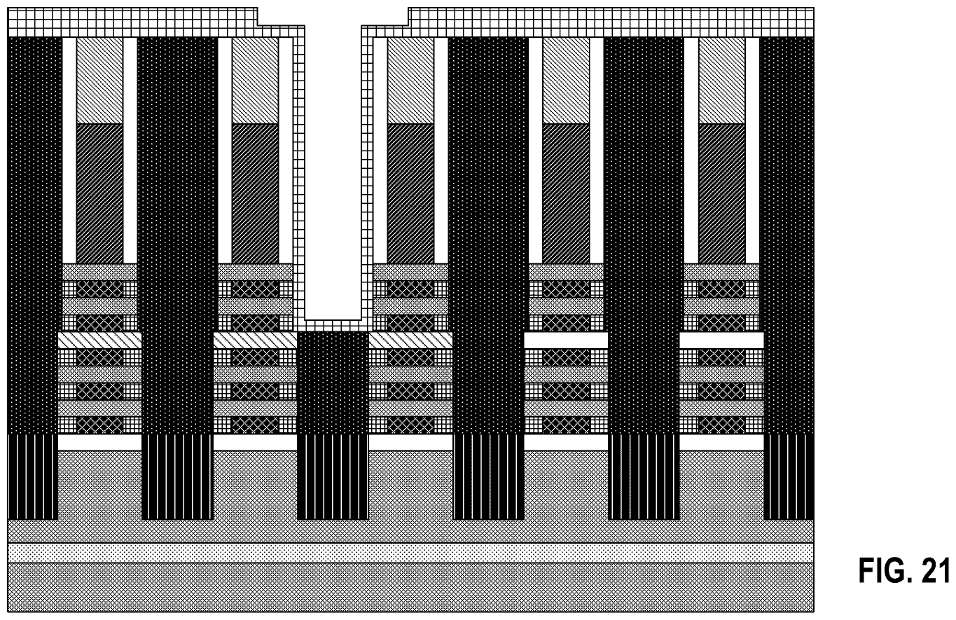

FIG. 21 illustrates the semiconductor device after the formation of the liner, in accordance with some embodiments. In some embodiments, an additional layer of liner is formed over the semiconductor device.

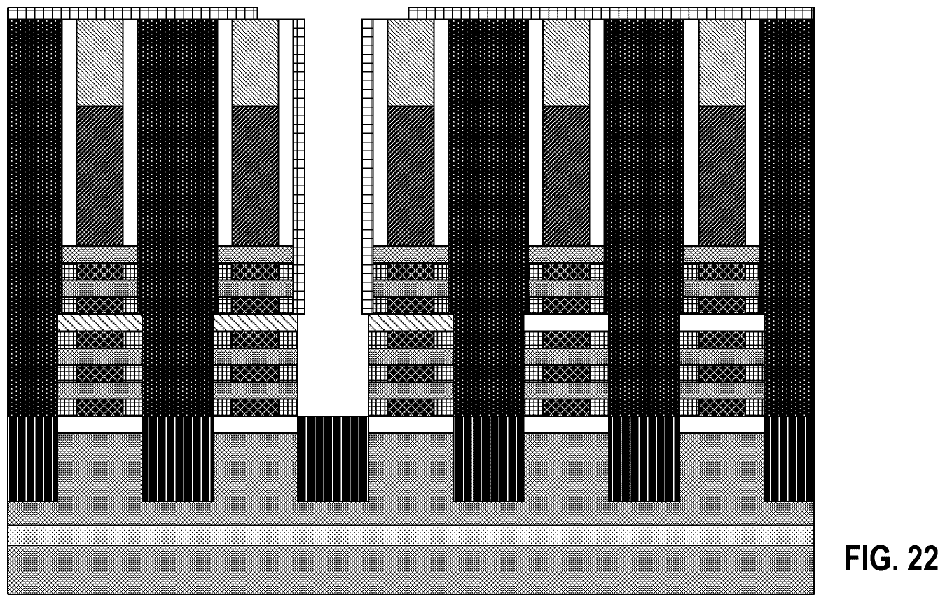

FIG. 22 illustrates the semiconductor device after the recession of the semiconductor device, in accordance with some embodiments. In some embodiments, portions of the liner, and the oxide layer are removed to expose a placeholder.

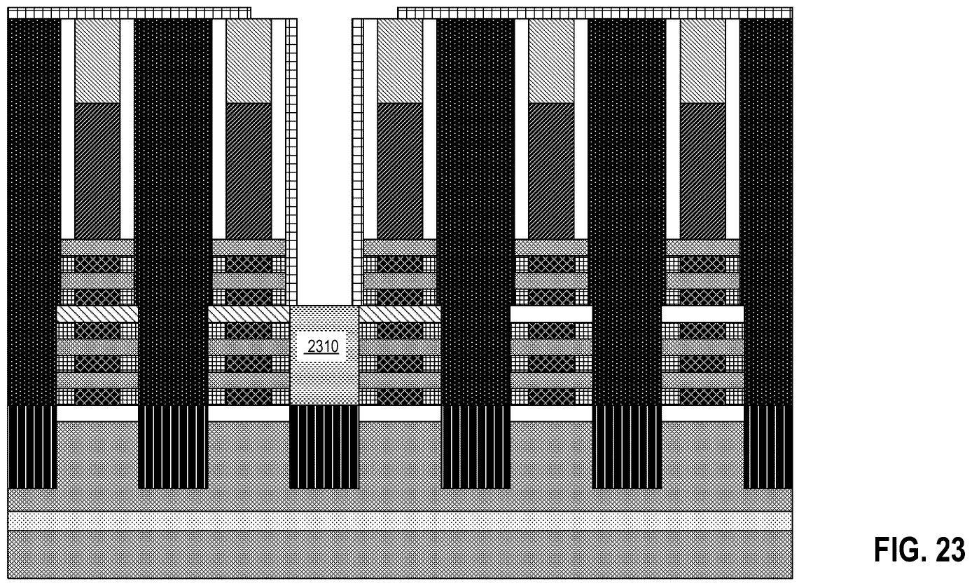

FIG. 23 illustrates the semiconductor device after the formation of the bottom doped region, in accordance with some embodiments. In some embodiments, a bottom doped region 2310 is formed over the placeholder.

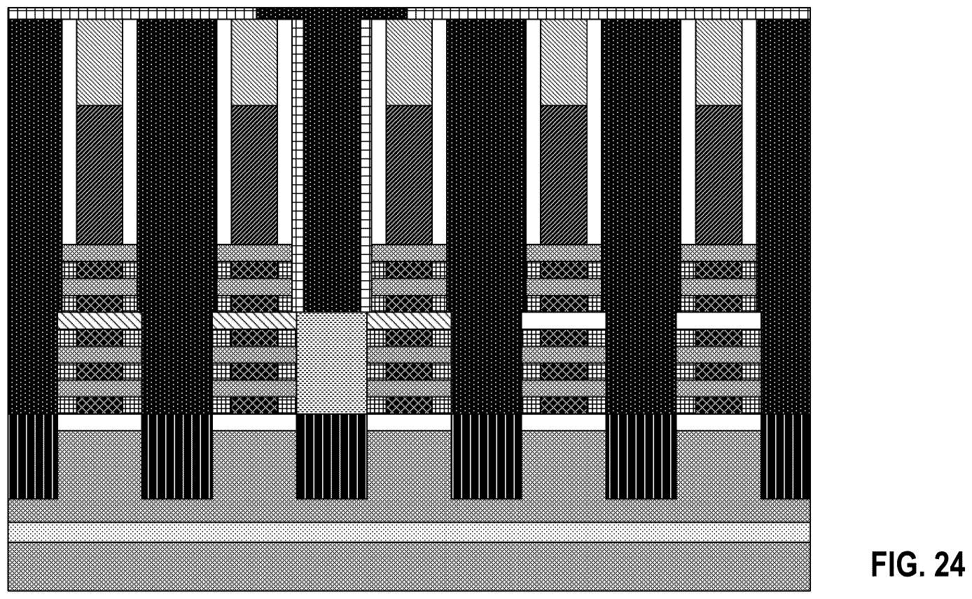

FIG. 24 illustrates the semiconductor device after the formation of the oxide layer, in accordance with some embodiments. In some embodiments, an oxide layer is formed over the bottom doped region 2310.

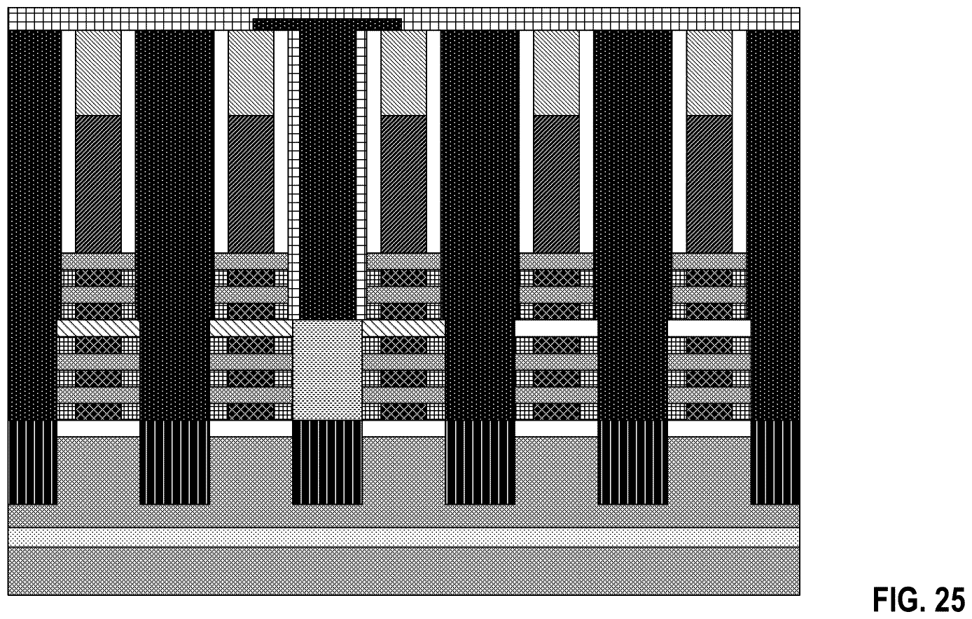

FIG. 25 illustrates the semiconductor device after the formation of the liner, in accordance with some embodiments. In some embodiments, a liner layer is formed over the semiconductor device.

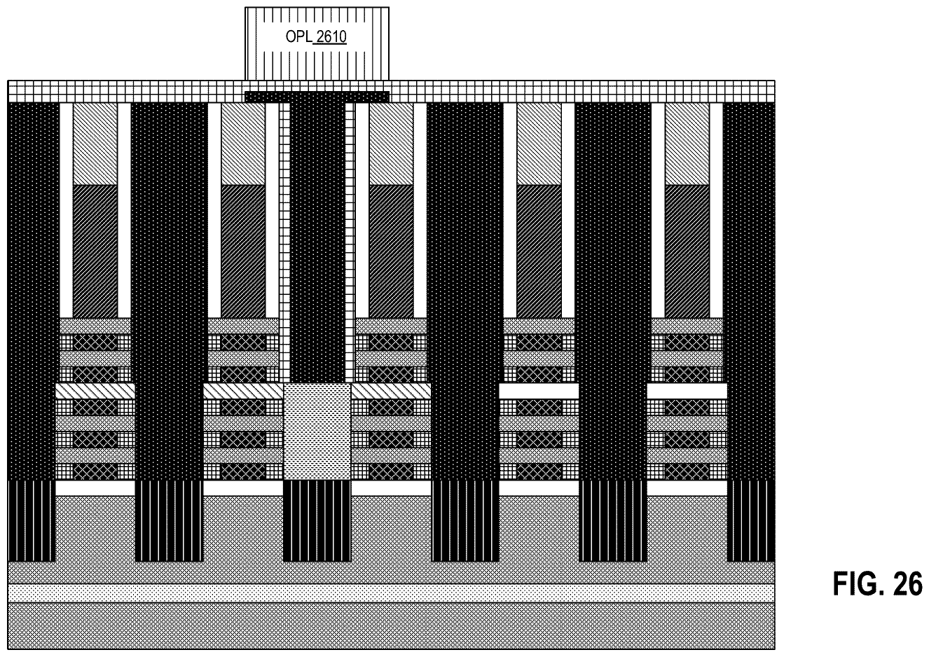

FIG. 26 illustrates the semiconductor device after the formation of the OPL, in accordance with some embodiments. In some embodiments, an OPL 2610 is formed over the section of the semiconductor device that includes the bottom doped region 2310.

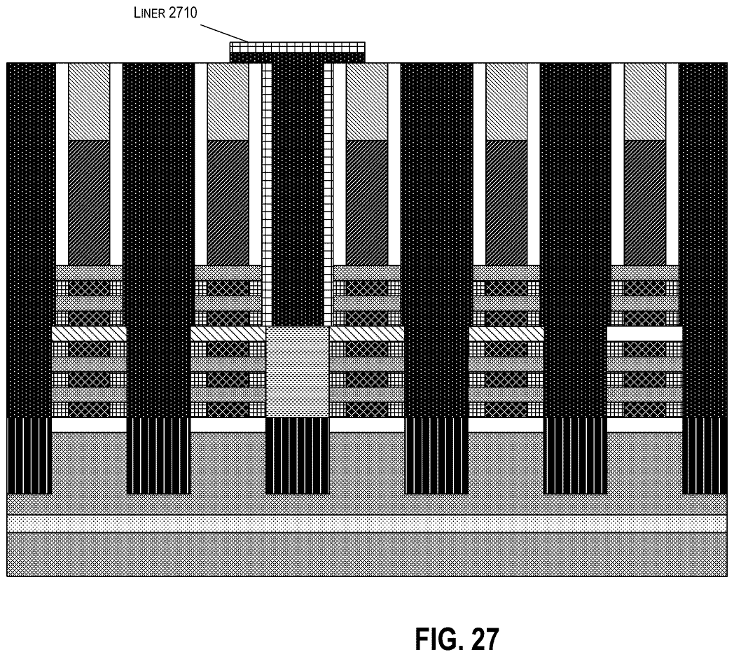

FIG. 27 illustrates the semiconductor device after the removal of the OPL, in accordance with some embodiments. In some embodiments, the OPL is removed and replaced by a liner 2710.

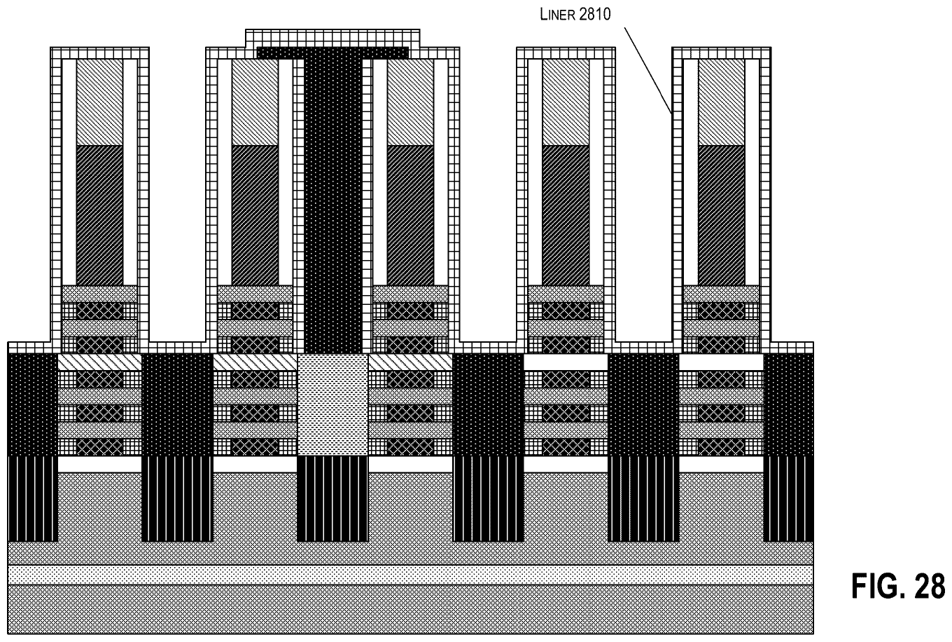

FIG. 28 illustrates the semiconductor device after the recession of the oxide layer, in accordance with some embodiments. In some embodiments, the oxide layer is recessed and the exposed sidewalls of the stacks are covered by liner 2810.

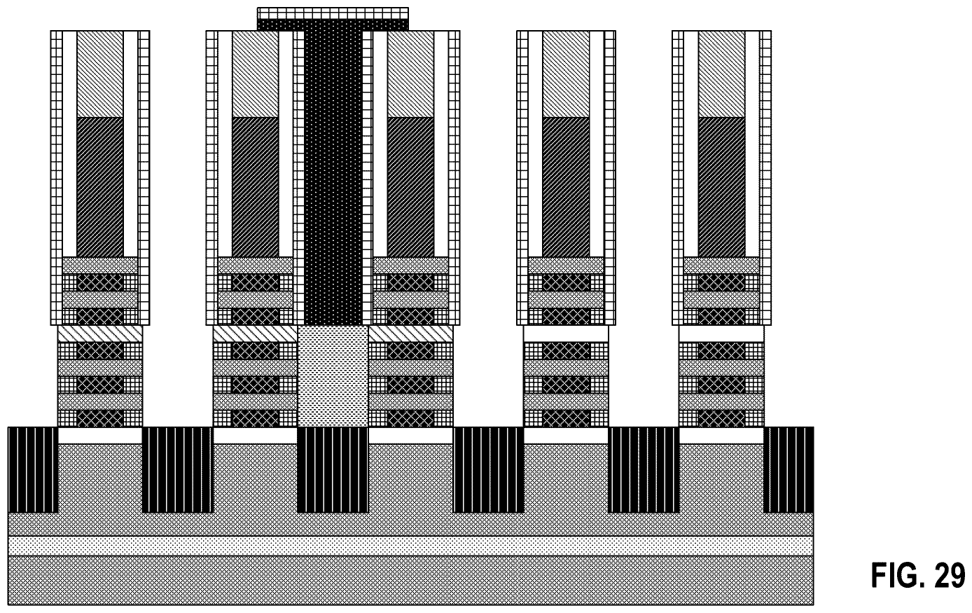

FIG. 29 illustrates the semiconductor device after the removal of the liner, in accordance with some embodiments. In some embodiments, the top surface of the liner and the oxide layer underneath are removed.

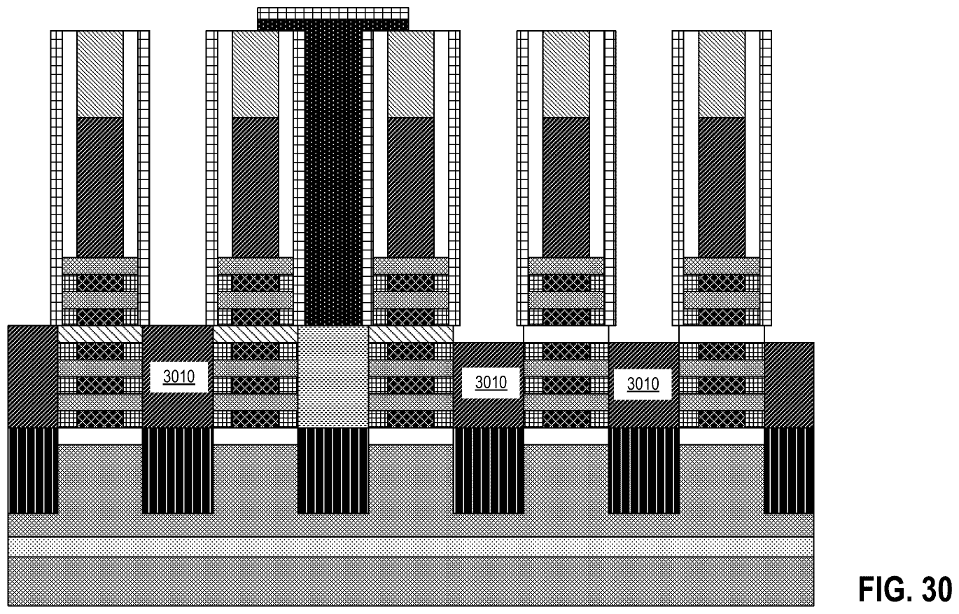

FIG. 30 illustrates the semiconductor device after the formation of the bottom doped region, in accordance with some embodiments. In some embodiments, a bottom doped region 3010 is formed over a placeholder.

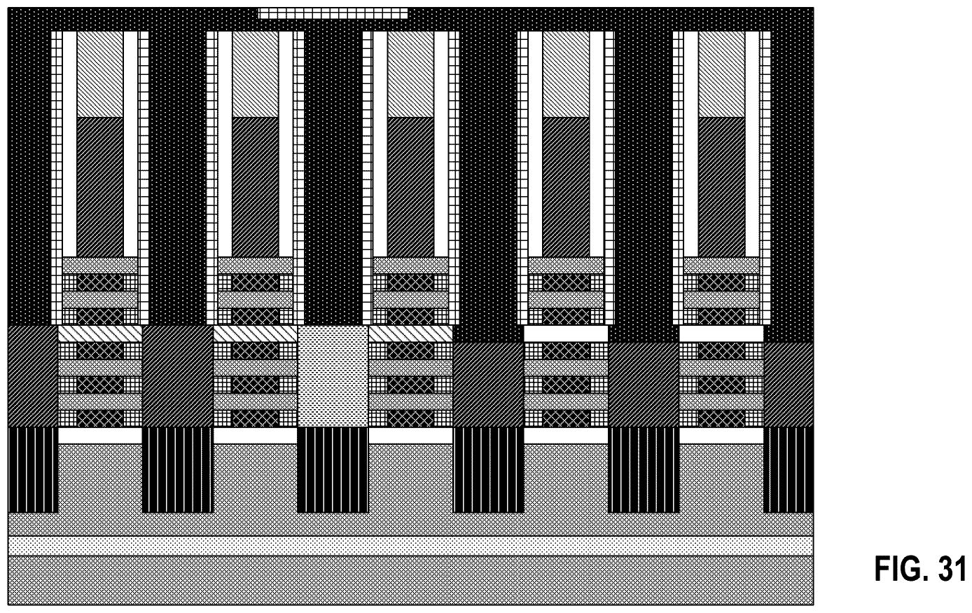

FIG. 31 illustrates the semiconductor device after the formation of the oxide layer, in accordance with some embodiments. In some embodiments, an oxide layer is formed to cover the semiconductor device.

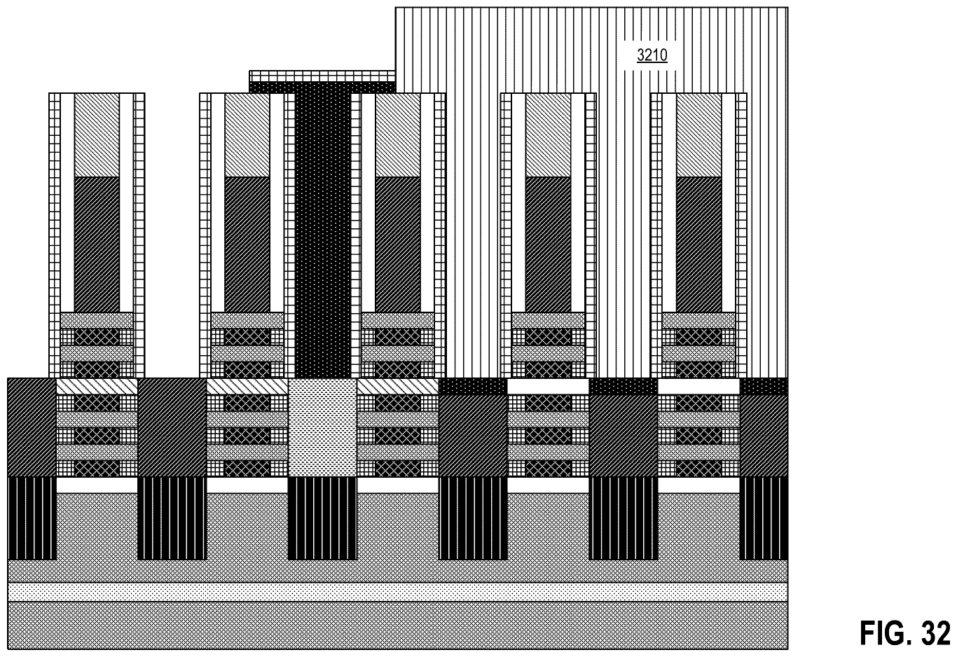

FIG. 32 illustrates the semiconductor device after the recession of the oxide layer, in accordance with some embodiments. In some embodiments, an OPL 3210 is formed over the logic region, and the oxide layer is recessed in the passive region.

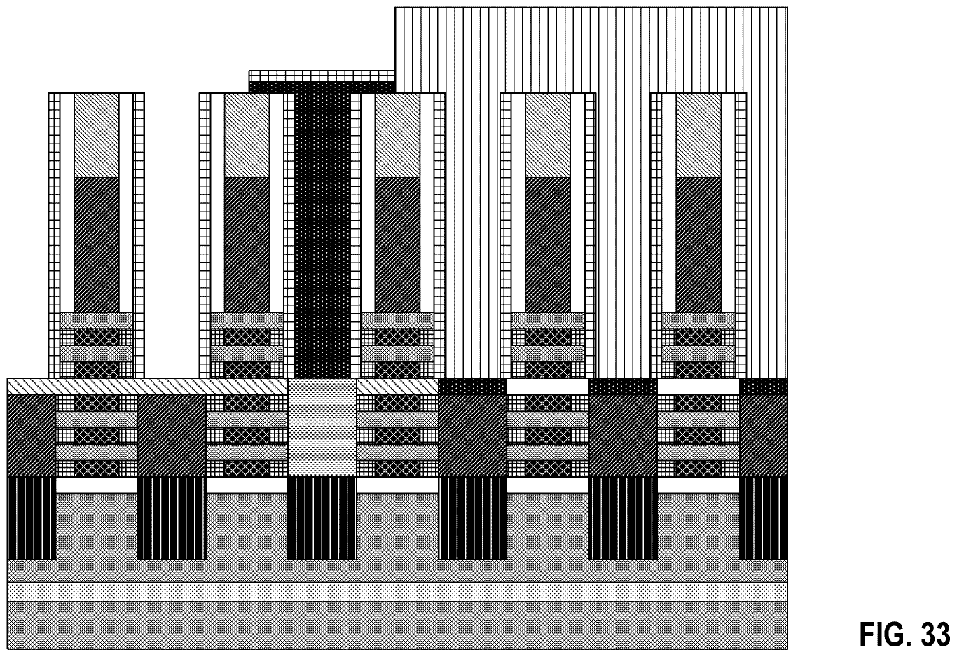

FIG. 33 illustrates the semiconductor device after the doping of the bottom doped region, in accordance with some embodiments. In some embodiments, the top surface of the exposed portions of the passive region is lightly doped, while the logic region remains intact.

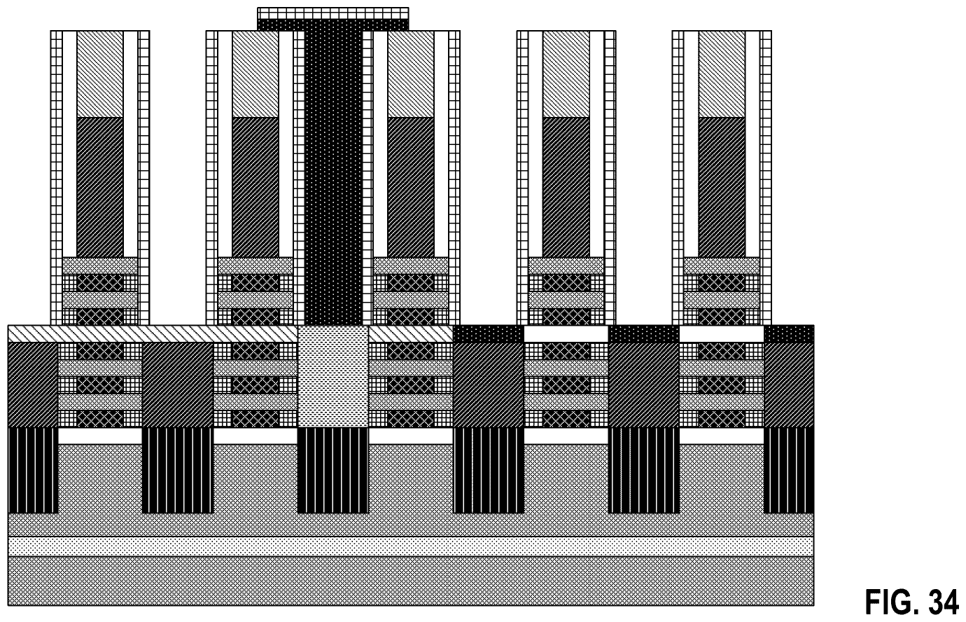

FIG. 34 illustrates the semiconductor device after the removal of the OPL, in accordance with some embodiments. In some embodiments, the OPL is removed.

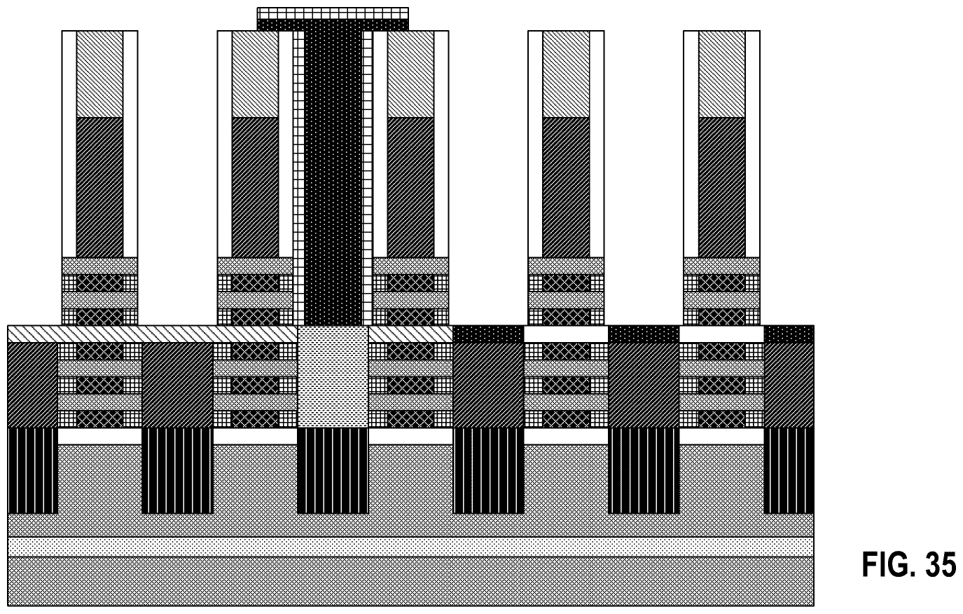

FIG. 35 illustrates the semiconductor device after the removal of the liner, in accordance with some embodiments. In some embodiments, the liner layer is removed.

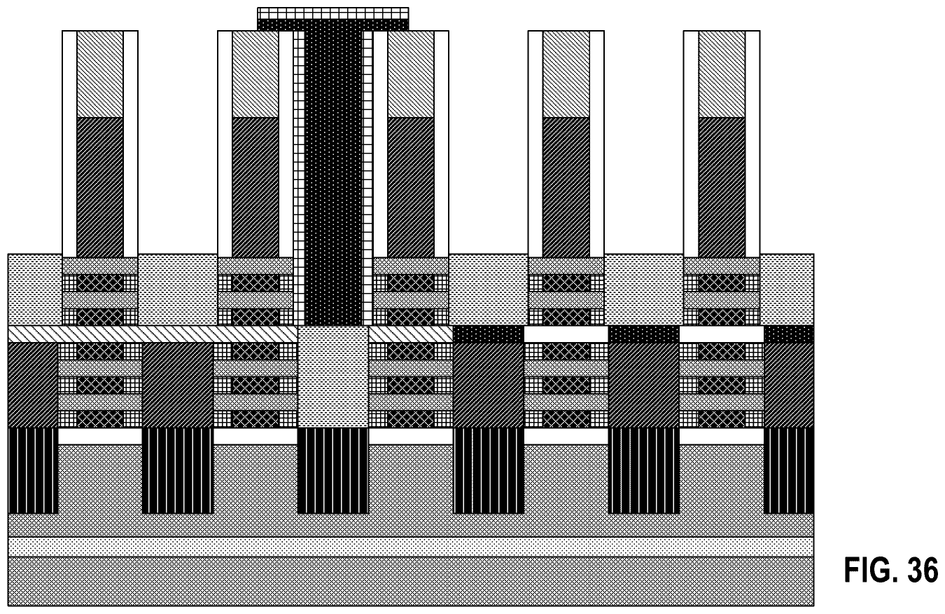

FIG. 36 illustrates the semiconductor device after the formation of the top doped region, in accordance with some embodiments. In some embodiments, the top doped region is formed within the stacks.

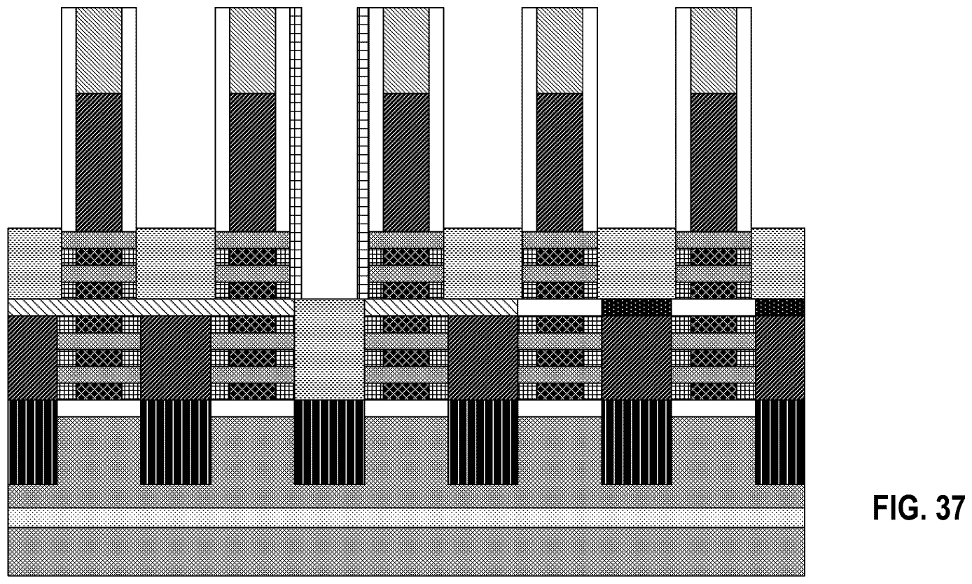

FIG. 37 illustrates the semiconductor device after the removal of the oxide, in accordance with some embodiments. In some embodiments, the oxide layer is removed.

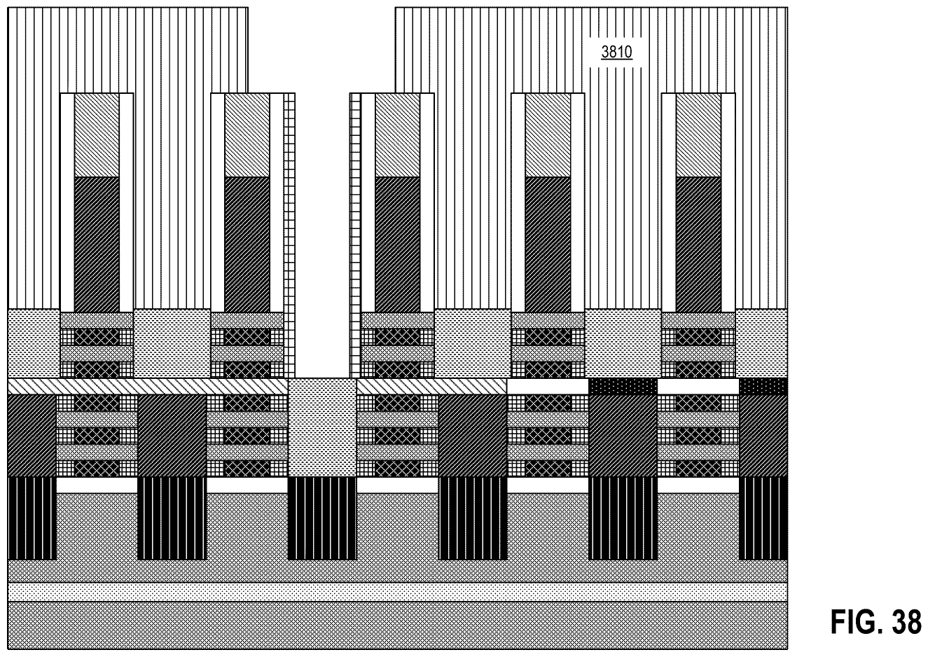

FIG. 38 illustrates the semiconductor device after the formation of the OPL, in accordance with some embodiments. In some embodiments, an OPL 3810 is formed over the PFET.

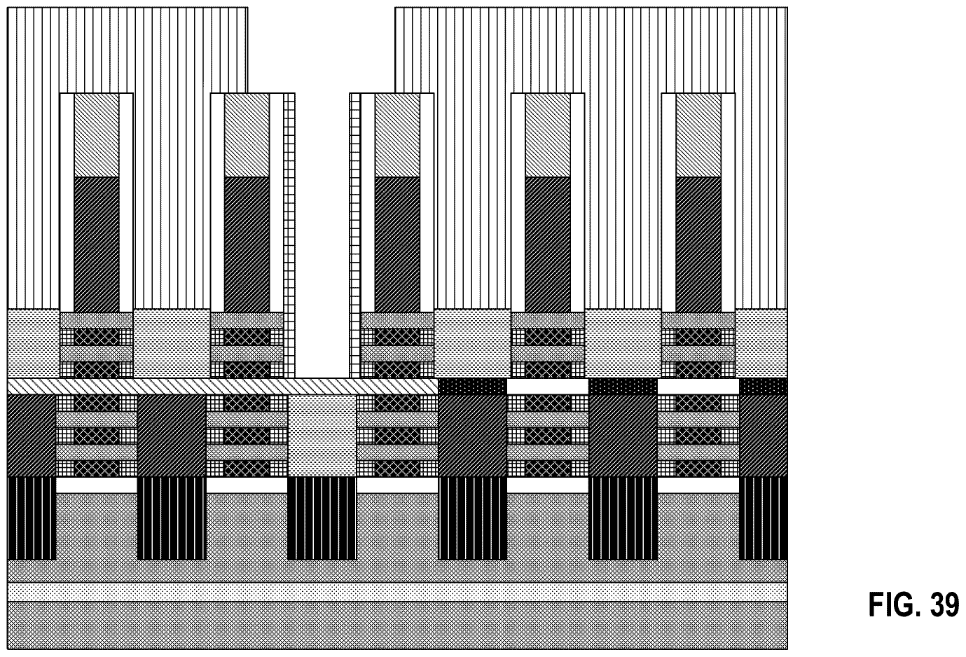

FIG. 39 illustrates the semiconductor device after the doping of the top doped region, in accordance with some embodiments. In some embodiments, the top surface of the exposed portions semiconductor device is lightly doped.

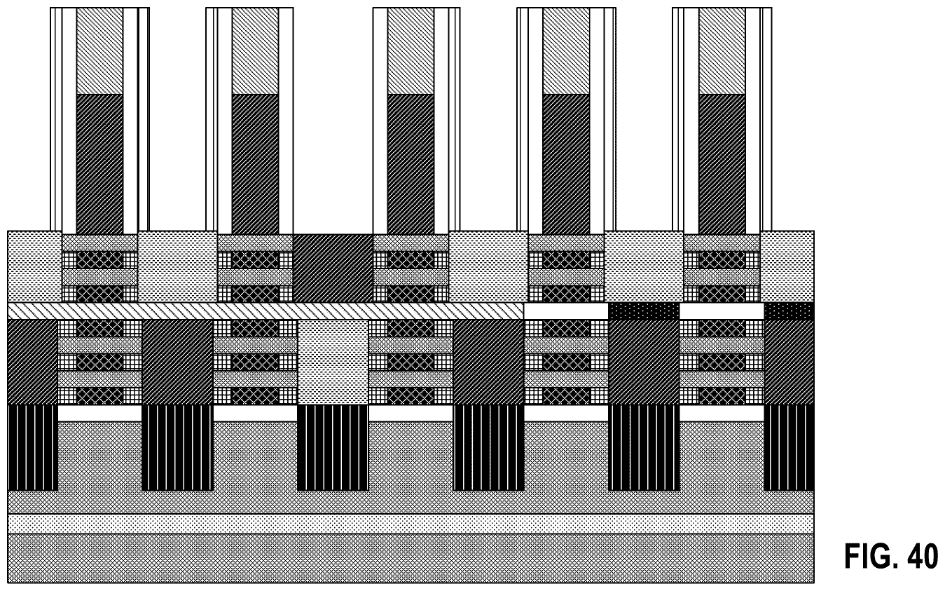

FIG. 40 illustrates the semiconductor device after the removal of the OPL, in accordance with some embodiments. In some embodiments, the OPL and the liner are removed and the top doped regions are formed.

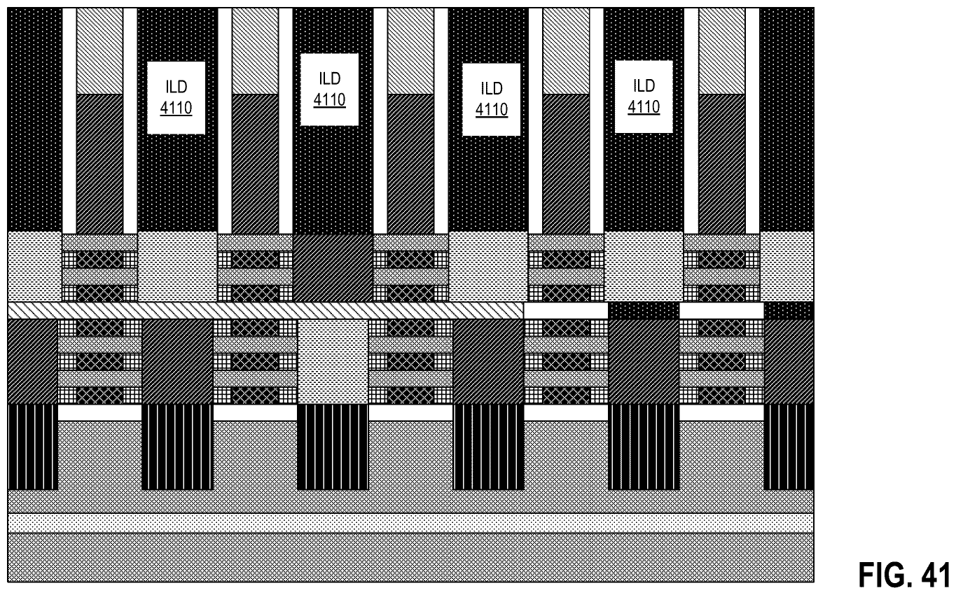

FIG. 41 illustrates the semiconductor device after the formation of the interlayer dielectric layer, in accordance with some embodiments. In some embodiments, the ILD 4110 is formed over the semiconductor device.

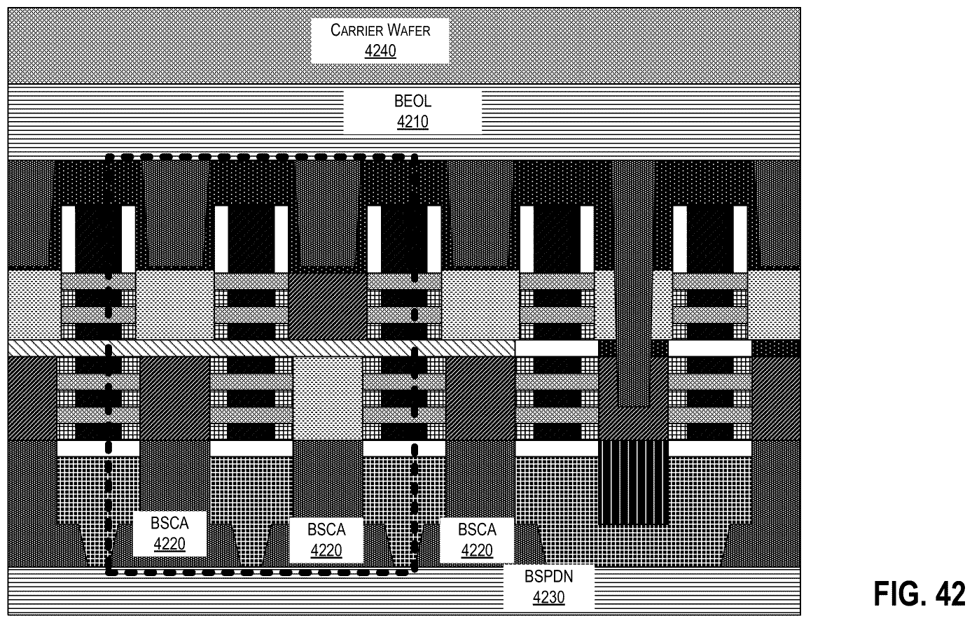

FIG. 42 illustrates the semiconductor device after the middle of line processes, and the back end of line processes, in accordance with some embodiments. In some embodiments, the middle of line are performed. The back end of line, BEOL 4210, the BSCA 4220 and the backside power delivery network, BSPDN 4230, are formed. In some embodiments, the gate regions can be formed by a replacement metal gate (RMG) process to fabricate metal gate electrodes. In some embodiments, RMG can involve the replacement of the SiGe with a metal material, which can offer improved electrical performance and scalability. The metal gates can provide electrostatic control of the channel region, reduce leakage currents, and improve the semiconductor device's performance. In some embodiments, the metal gates can further provide improved control over the work function, enable matching of threshold voltages, and reduce semiconductor device variability.

In various embodiments, carrier wafer bonding, also known as wafer-to-wafer bonding or chip-to-wafer bonding, is performed to join two semiconductor devices together by creating a permanent bond between them, e.g., via a carrier wafer 4240. In some embodiments, the two semiconductor devices can be brought into contact and bonded at the atomic or molecular level, to create an interface. In an embodiment, the two semiconductor devices are brought into contact under controlled conditions, such as controlled pressure and temperature, to enable atomic or molecular bonding at the interface. Such bonding can be done at room temperature or with elevated temperatures. Alternatively, in some embodiments, an electric field and elevated temperature are utilized to create a bond. One semiconductor device can be made of semiconductor material, while the other can be a glass or silicon dioxide (SiO2) wafer. The electric field can cause ions in the glass or SiO2 to migrate and chemically bond with the semiconductor material in the other semiconductor device. In additional embodiments, a thin metal layer or metal alloy can be used as an intermediate bonding layer between the semiconductor devices. The metal layer can be deposited or transferred onto one or both semiconductor device surfaces, and the semiconductor devices can then be brought into contact and subjected to temperature and pressure to create a metallic bond.

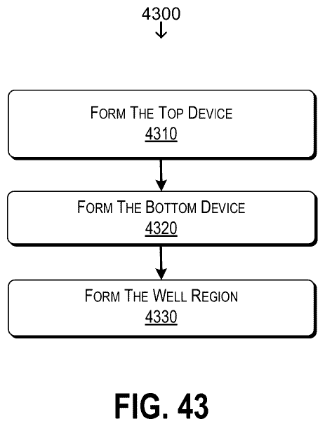

FIG. 43 illustrates a block diagram of a method 4300 for forming the semiconductor device, in accordance with some embodiments. As shown by block 4310, a top device is formed.

As shown by block 4320, a bottom device is formed.

As shown by block 4330, a well region is formed which electrically separate the top device from the bottom device.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a top device comprising:
a top N-type doped region and a top P-type doped region separated by a top gate region; and
a first frontside contact and a second frontside contact over the top N-type doped region and the top P-type doped region, respectively;
a bottom device comprising:
a bottom P-type doped region and bottom N-type doped region separated by a bottom gate region; and
a first backside contact and a second backside contact below the bottom N-type doped region and the bottom P-type doped region, respectively; and
a well region electrically connecting the top device to the bottom device.

2. The semiconductor device of claim 1, wherein each of the top device and the bottom device further comprises a set of nanosheet channels extended horizontally across a gate.

3. The semiconductor device of claim 1, wherein:
the top device and the bottom device form a vertical device and a lateral device in a same structure; and
the vertical device and the lateral device are in parallel.

4. The semiconductor device of claim 1, wherein the well region is at least one of: an in situ-doped intermediate semiconductor layer or an implant layer.

5. The semiconductor device of claim 1, further comprising an input contact and an output contact, wherein:
at least one of the top device or the bottom device is a bipolar junction; and
the input contact and the output contact are at a same metallization level.

6. The semiconductor device of claim 1, further comprising an input contact and an output contact, wherein:
the semiconductor device forms a diode; and
the input contact and the output contact are located on opposite sides of the semiconductor device or a same side of the semiconductor device.

7. The semiconductor device of claim 2, wherein:
the set of nanosheet channels is adjacent to an active device layer and is electrically connected; and
the top gate region and the bottom gate region are adjacent to the active device layer and are electrically isolated.

8. The semiconductor device of claim 1, wherein the well region is an N-well region or a P-well region.

9. The semiconductor device of claim 1, wherein the well region is electrically connected to the top P-type doped region, the top N-type doped region, the bottom P-type doped region, and the bottom N-type doped region.

10. A method for fabrication of a semiconductor device, the method comprising:
forming a top device comprising:
forming a top N-type doped region and a top P-type doped region separated by a top gate region; and
forming a first frontside contact and a second frontside contact over the top N-type doped region and the top P-type doped region, respectively;
forming a bottom device comprising:
forming a bottom P-type doped region and bottom N-type doped region separated by a bottom gate region; and
forming a first backside contact and a second backside contact below the bottom N-type doped region and the bottom P-type doped region, respectively; and
forming a well region electrically connecting the top device to the bottom device.

11. The method of claim 10, wherein forming each of the top device and the bottom device further comprises forming a set of nanosheet channels extended horizontally across a gate.

12. The method of claim 10, wherein the top device and the bottom device form a vertical device and a lateral device in a same structure, wherein the vertical device and the lateral device are in parallel.

13. The method of claim 10, wherein the well region is at least one of: an in situ-doped intermediate semiconductor layer or an implant layer.

14. The method of claim 10, further comprising:
forming an input contact and an output contact;
wherein at least one of the top device or the bottom device is a bipolar junction; and
wherein the input contact and the output contact are at a same metallization level.

15. The method of claim 10, further comprising forming an input contact and an output contact, wherein:
the semiconductor device forms a diode; and
the input contact and the output contact are located on opposite sides of the semiconductor device or a same side of the semiconductor device.

16. The method of claim 11, wherein the set of nanosheet channels is adjacent to an active device layer and is electrically connected, and wherein the top gate region and the bottom gate region are adjacent to the active device layer and are electrically isolated.

17. The method of claim 10, further comprising doping the well region with an N-type dopant or a P-type dopant.

18. The method of claim 10, further comprising electrically connecting the well region to the top P-type doped region, the top N-type doped region, the bottom N-type doped region and the bottom N-type doped region.

19. A semiconductor device, comprising:
a top device comprising a top N-type doped region and a top P-type doped region separated by a top gate region;
a bottom device comprising a bottom P-type doped region and bottom N-type doped region separated by a bottom gate region; and
a well region electrically connecting the top device to the bottom device.

20. The semiconductor device of claim 19, further comprising:
a first frontside contact and a second frontside contact over the top N-type doped region and the top P-type doped region, respectively; and
a first backside contact and a second backside contact below the bottom N-type doped region and the bottom P-type doped region, respectively,
wherein each of the top device and the bottom device further comprises a set of nanosheet channels extended horizontally across a gate.
